(19) United States
(12) Patent Application Publication
(10) Pub. No.: US 2026/0088929 A1
(43) Pub. Date: Mar. 26, 2026

(54) MACHINE LEARNING BASED ADAPTIVE QUANTIZATION FOR LOW DENSITY PARITY CHECK

(71) Applicant: QUALCOMM Incorporated, San Diego, CA (US)

(72) Inventors: David YUNUSOV, Holon (IL); Assaf TOUBOUL, Netanya (IL); Gideon Shlomo KUTZ, Ramat Hasharon (IL); Amit BAR-OR TILLINGER, Tel-Aviv (IL)

(21) Appl. No.: 18/896,580

(22) Filed: Sep. 25, 2024

(51) Int. Cl. H04L 1/00

(52) U.S. Cl. CPC H04L 1/0057; H04L 1/0054

(57) ABSTRACT

A wireless device may receive a first code block of one or more code blocks associated with a transport block for the wireless device. The wireless device may output, using a neural network model associated with the wireless device, a set of low-density parity-check (LDPC) quantization values for a set of iterations of an LDPC decoding procedure for the first code block. In some examples, the set of LDPC quantization values may include respective LDPC quantization values for respective iterations of the set of iterations. The wireless device may perform one or more iterations of the LDPC decoding procedure for the first code block in accordance with one or more LDPC quantization values of the set of LDPC quantization values output using the neural network model.

### FIELD OF TECHNOLOGY

The following relates to wireless communications, including machine learning based adaptive quantization for low density parity check (LDPC).

### BACKGROUND

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM). A wireless multiple-access communications system may include one or more base stations, each supporting wireless communication for communication devices, which may be known as user equipment (UE).

### SUMMARY

The systems, methods, and devices of this disclosure each have several innovative aspects, no single one of which is solely responsible for the desirable attributes disclosed herein.

A method for wireless communications by a wireless device is described. The method may include receiving a first code block of one or more code blocks associated with a transport block for the wireless device, outputting, using a neural network model associated with the wireless device, a set of multiple low-density parity-check (LDPC) quantization values for a set of multiple iterations of an LDPC decoding procedure for the first code block, where the set of multiple LDPC quantization values include respective LDPC quantization values for respective iterations of the set of multiple iterations, and performing one or more iterations of the LDPC decoding procedure for the first code block in accordance with one or more LDPC quantization values of the set of multiple LDPC quantization values output using the neural network model.

A wireless device for wireless communications is described. The wireless device may include one or more memories storing processor executable code, and one or more processors coupled with the one or more memories. The one or more processors may individually or collectively be operable to execute the code to cause the wireless device to receive a first code block of one or more code blocks associated with a transport block for the wireless device, output, using a neural network model associated with the wireless device, a set of multiple LDPC quantization values for a set of multiple iterations of an LDPC decoding procedure for the first code block, where the set of multiple LDPC quantization values include respective LDPC quantization values for respective iterations of the set of multiple iterations, and perform one or more iterations of the LDPC decoding procedure for the first code block in accordance with one or more LDPC quantization values of the set of multiple LDPC quantization values output using the neural network model.

Another wireless device for wireless communications is described. The wireless device may include means for receiving a first code block of one or more code blocks associated with a transport block for the wireless device, means for outputting, using a neural network model associated with the wireless device, a set of multiple LDPC quantization values for a set of multiple iterations of an LDPC decoding procedure for the first code block, where the set of multiple LDPC quantization values include respective LDPC quantization values for respective iterations of the set of multiple iterations, and means for performing one or more iterations of the LDPC decoding procedure for the first code block in accordance with one or more LDPC quantization values of the set of multiple LDPC quantization values output using the neural network model.

A non-transitory computer-readable medium storing code for wireless communications is described. The code may include instructions executable by one or more processors to receive a first code block of one or more code blocks associated with a transport block for the wireless device, output, using a neural network model associated with the wireless device, a set of multiple LDPC quantization values for a set of multiple iterations of an LDPC decoding procedure for the first code block, where the set of multiple LDPC quantization values include respective LDPC quantization values for respective iterations of the set of multiple iterations, and perform one or more iterations of the LDPC decoding procedure for the first code block in accordance with one or more LDPC quantization values of the set of multiple LDPC quantization values output using the neural network model.

Some examples of the method, wireless devices, and non-transitory computer-readable medium described herein may further include operations, features, means, or instructions for inputting, into the neural network model, a set of input parameters, where the set of input parameters includes at least mutual information of a set of multiple log-likelihood ratios (LLRs) associated with demodulating the first code block and a histogram associated with the set of multiple LLRs associated with demodulating the first code block, and where the set of multiple LDPC quantization values output from the neural network model may be based on the set of input parameters.

In some examples of the method, wireless devices, and non-transitory computer-readable medium described herein, each respective LDPC quantization value of the set of multiple LDPC quantization values may be associated with a respective set of input parameters and a given LDPC quantization value may be based on a previous iteration of LLRs output from an LDPC decoder that performs the LDPC decoding procedure.

In some examples of the method, wireless devices, and non-transitory computer-readable medium described herein, performing the one or more iterations of the LDPC decoding procedure for the first code block may include operations, features, means, or instructions for performing a first iteration of the one or more iterations in accordance with a first LDPC quantization value of the one or more LDPC quantization values.

In some examples of the method, wireless devices, and non-transitory computer-readable medium described herein, the first iteration of the LDPC decoding procedure results in cyclic redundancy check (CRC) failure for the first code block and the method, apparatuses, and non-transitory computer-readable medium may include further operations, features, means, or instructions for performing a second iteration of the one or more iterations in accordance with a second LDPC quantization value of the one or more LDPC quantization values and refraining from performing additional iterations of the set of multiple iterations of the LDPC decoding procedure for the first code block based on the second iteration resulting in CRC pass for the first code block.

Some examples of the method, wireless devices, and non-transitory computer-readable medium described herein may further include operations, features, means, or instructions for performing a second LDPC decoding procedure for a second code block of the one or more code blocks based on CRC pass for the first code block.

In some examples of the method, wireless devices, and non-transitory computer-readable medium described herein, each of the set of multiple iterations of the LDPC decoding procedure results in CRC failure for the first code block and the method, apparatuses, and non-transitory computer-readable medium may include further operations, features, means, or instructions for performing one or more additional iterations of the LDPC decoding procedure for the first code block in accordance with one or more fixed LDPC quantization values, where the one or more fixed LDPC quantization values include respective fixed LDPC quantization values for respective additional iterations of the one or more additional iterations.

In some examples of the method, wireless devices, and non-transitory computer-readable medium described herein, each of the set of multiple iterations of the LDPC decoding procedure results in CRC failure for the first code block and the method, apparatuses, and non-transitory computer-readable medium may include further operations, features, means, or instructions for refraining from decoding additional code blocks of the one or more code blocks based on each of the set of multiple iterations of the LDPC decoding procedure resulting in CRC failure for the first code block.

In some examples of the method, wireless devices, and non-transitory computer-readable medium described herein, the neural network model outputs the set of multiple LDPC quantization values for the set of multiple iterations of the LDPC decoding procedure for the first code block to an LDPC decoder associated with the wireless device.

In some examples of the method, wireless devices, and non-transitory computer-readable medium described herein, training, prior to outputting the set of multiple LDPC quantization values, the neural network model in accordance with a multi-class classification, where each class of a set of classes associated with the multi-class classification indicates one or more allowed LDPC quantizations values for each respective iteration of the set of multiple iterations.

Some examples of the method, wireless devices, and non-transitory computer-readable medium described herein may further include operations, features, means, or instructions for performing, prior to the LDPC decoding procedure of the first code block, a second decoding procedure for the first code block that results in an CRC failure for the first code block, where performing the one or more iterations of the LDPC decoding procedure for the first code block may be based on the second decoding procedure resulting in CRC failure for the first code block.

Some examples of the method, wireless devices, and non-transitory computer-readable medium described herein may further include operations, features, means, or instructions for performing, at the neural network model, a first iteration of a prediction procedure that outputs a first LDPC success prediction value associated with decoding the first code block, where performing the one or more iterations of the LDPC decoding procedure for the first code block may be based on the first LDPC success prediction value satisfying a prediction value threshold.

Some examples of the method, wireless devices, and non-transitory computer-readable medium described herein may further include operations, features, means, or instructions for performing, at the neural network model, a second iteration of the prediction procedure that outputs a second LDPC success prediction value associated with decoding a second code block of the one or more code blocks and refraining to perform a second LDPC decoding procedure for the second code block based on the second LDPC success prediction value not satisfying the prediction value threshold.

In some examples of the method, wireless devices, and non-transitory computer-readable medium described herein, each respective LDPC quantization value indicates a respective quantity of bits for each LLR of a set of LLRs for the first code block.

Details of one or more implementations of the subject matter described in this disclosure are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of a wireless communications system that supports machine learning based adaptive quantization for low density parity check (LDPC) in accordance with one or more aspects of the present disclosure.

FIG. 2 shows an example of a wireless communications system that supports machine learning based adaptive quantization for LDPC in accordance with one or more aspects of the present disclosure.

FIG. 3 shows an example of a machine learning based decoding procedure that supports machine learning based adaptive quantization for LDPC in accordance with one or more aspects of the present disclosure.

FIG. 4 shows an example of a process flow that supports machine learning based adaptive quantization for LDPC in accordance with one or more aspects of the present disclosure.

FIGS. 5 and 6 show block diagrams of devices that support machine learning based adaptive quantization for LDPC in accordance with one or more aspects of the present disclosure.

FIG. 7 shows a block diagram of a communications manager that supports machine learning based adaptive quantization for LDPC in accordance with one or more aspects of the present disclosure.

FIG. 8 shows a diagram of a system including a device that supports machine learning based adaptive quantization for LDPC in accordance with one or more aspects of the present disclosure.

FIG. 9 shows a flowchart illustrating methods that support machine learning based adaptive quantization for LDPC in accordance with one or more aspects of the present disclosure.

### DETAILED DESCRIPTION

In some examples of wireless communications, a wireless device (e.g., a user equipment (UE) or network entity) may operate in accordance with low density parity check (LDPC) and log-likelihood ratios (LLRs) to increase the reliability of the wireless device successfully decoding a received wireless message. For example, a given LLR may be associated with a given bit of a received wireless message, such that the LLR is a probability that the received bit was either transmitted as a 0 or a 1. Additionally, LDPC decoding may be an iterative process where LLRs are updated in each iteration to improve error correction. For instance, an LDPC decoder of the wireless device may start with the initial LLRs obtained from a demodulator of the wireless device, where the initial LLRs reflect the received signal quality and noise level. In some examples, the LLRs are iteratively refined by repeatedly passing messages between variable and check nodes until convergence is achieved or a threshold quantity of iterations is reached. In some cases, however, LDPC decoding is a large power consumer at the wireless device. Additionally, in scenarios where a wireless message is received with a high signal to noise ratio (SNR) it may be advantageous to dynamically reduce complexity associated with generating LLRs at the LDPC decoder.

The wireless device may operate in accordance with an intelligent decoder scheme for a reduction power consumption associated with LDPC decoding. For example, the intelligent decoder scheme may implement a machine learning classification algorithm for selecting different fixed point quantizations within the LDPC decoder. The intelligent decoder scheme reduces LDPC power by determining the quantization (e.g., LLR bit-width) per LDPC decoding iteration. For example, the wireless device may train a neural network model which predicts the quantization per iteration of LDPC decoding prior to entering LDPC decoder. In some examples, the neural network model classifies code block of received data to numerous classes and selects the LDPC quantization per iteration. Each class represents lower bit quantization (e.g., 2-bits, 4-bits, or 6-bits) with all possible combinations to reduce power consumption at the LDPC decoder. In some examples, the LDPC quantization may be independent of (e.g., may not depend on) the channel statistics or channel profile. Further, reducing the LLR bit-width (e.g., the quantization), results in a power consumption reduction as fewer read and write operations for memory within the LDPC decoder are performed (e.g., fewer read from memory operations are performed and fewer write to memory operations are performed).

Additionally, or alternatively, the neural network model may implement LDPC success predictor (e.g., suggests whether to enter LDPC), thus saving entire LDPC decoder power in cases where LDPC decoding success is determined to be below a configured threshold. By reducing the LLR bit-width associated with one or more iterations of LDPC decoding, the wireless device may reduce power expenditure associated with generating LLRs at the LDPC decoder. Additionally, due to the neural network model generating a predicted class of LDPC quantization values based on varying channel conditions, the neural network model may reduce the bit-width associated with LLRs while maintaining performance of the LDPC decoder above a performance threshold. As such, the wireless device may reduce power expenditure while maintaining communication quality.

Aspects of the disclosure are initially described in the context of wireless communications systems, a machine learning based decoding procedure, and a process flow. Aspects of the disclosure are further illustrated by and described with reference to apparatus diagrams, system diagrams, and flowcharts that relate to machine learning based adaptive quantization for LDPC.

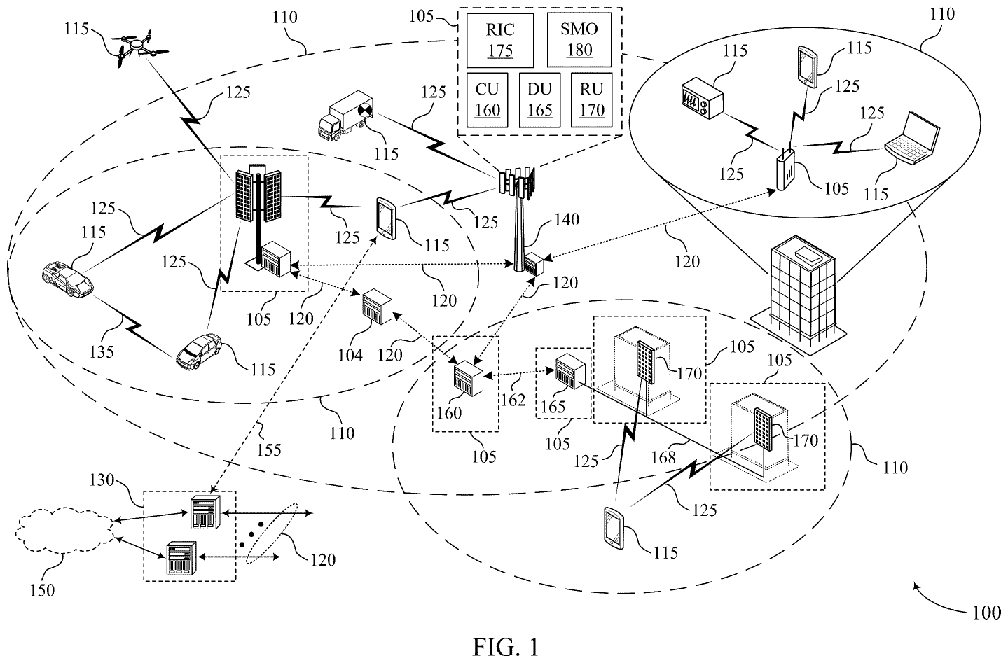

FIG. 1 shows an example of a wireless communications system 100 that supports machine learning based adaptive quantization for LDPC in accordance with one or more aspects of the present disclosure. The wireless communications system 100 may include one or more devices, such as one or more network devices (e.g., network entities 105), one or more UEs 115, and a core network 130. In some examples, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some examples, network entities 105 and UEs 115 may wirelessly communicate via communication link(s) 125 (e.g., a radio frequency (RF) access link). For example, a network entity 105 may support a coverage area 110 (e.g., a geographic coverage area) over which the UEs 115 and the network entity 105 may establish the communication link(s) 125. The coverage area 110 may be an example of a geographic area over which a network entity 105 and a UE 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or have different capabilities. Some example UEs 115 are illustrated in FIG. 1. The UEs 115 described herein may be capable of supporting communications with various types of devices in the wireless communications system 100 (e.g., other wireless communication devices, including UEs 115 or network entities 105), as shown in FIG. 1.

As described herein, a node of the wireless communications system 100, which may be referred to as a network node, or a wireless node, may be a network entity 105 (e.g., any network entity described herein), a UE 115 (e.g., any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, computing system, or the like may include disclosure of the UE 115, network entity 105, apparatus, device, computing system, or the like being a node. For example, disclosure that a UE 115 is configured to receive information from a network entity 105 also discloses that a first node is configured to receive information from a second node.

In some examples, network entities 105 may communicate with a core network 130, or with one another, or both. For example, network entities 105 may communicate with the core network 130 via backhaul communication link(s) 120 (e.g., in accordance with an S1, N2, N3, or other interface protocol). In some examples, network entities 105 may communicate with one another via backhaul communication link(s) 120 (e.g., in accordance with an X2, Xn, or other interface protocol) either directly (e.g., directly between network entities 105) or indirectly (e.g., via the core network 130). In some examples, network entities 105 may communicate with one another via a midhaul communication link 162 (e.g., in accordance with a midhaul interface protocol) or a fronthaul communication link 168 (e.g., in accordance with a fronthaul interface protocol), or any combination thereof. The backhaul communication link(s) 120, midhaul communication links 162, or fronthaul communication links 168 may be or include one or more wired links (e.g., an electrical link, an optical fiber link) or one or more wireless links (e.g., a radio link, a wireless optical link), among other examples or various combinations thereof. A UE 115 may communicate with the core network 130 via a communication link 155.

One or more of the network entities 105 or network equipment described herein may include or may be referred to as a base station 140 (e.g., a base transceiver station, a radio base station, an NR base station, an access point, a radio transceiver, a NodeB, an eNodeB (eNB), a next-generation NodeB or giga-NodeB (either of which may be referred to as a gNB), a 5G NB, a next-generation eNB (ng-eNB), a Home NodeB, a Home eNodeB, or other suitable terminology). In some examples, a network entity 105 (e.g., a base station 140) may be implemented in an aggregated (e.g., monolithic, standalone) base station architecture, which may be configured to utilize a protocol stack that is physically or logically integrated within one network entity (e.g., a network entity 105 or a single RAN node, such as a base station 140).

In some examples, a network entity 105 may be implemented in a disaggregated architecture (e.g., a disaggregated base station architecture, a disaggregated RAN architecture), which may be configured to utilize a protocol stack that is physically or logically distributed among multiple network entities (e.g., network entities 105), such as an integrated access and backhaul (IAB) network, an open RAN (O-RAN) (e.g., a network configuration sponsored by the O-RAN Alliance), or a virtualized RAN (vRAN) (e.g., a cloud RAN (C-RAN)). For example, a network entity 105 may include one or more of a central unit (CU), such as a CU 160, a distributed unit (DU), such as a DU 165, a radio unit (RU), such as an RU 170, a RAN Intelligent Controller (RIC), such as an RIC 175 (e.g., a Near-Real Time RIC (Near-RT RIC), a Non-Real Time RIC (Non-RT RIC)), a Service Management and Orchestration (SMO) system, such as an SMO system 180, or any combination thereof. An RU 170 may also be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (e.g., separate physical locations). In some examples, one or more of the network entities 105 of a disaggregated RAN architecture may be implemented as virtual units (e.g., a virtual CU (VCU), a virtual DU (VDU), a virtual RU (VRU)).

The split of functionality between a CU 160, a DU 165, and an RU 170 is flexible and may support different functionalities depending on which functions (e.g., network layer functions, protocol layer functions, baseband functions, RF functions, or any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some examples, the CU 160 may host upper protocol layer (e.g., layer 3 (L3), layer 2 (L2)) functionality and signaling (e.g., Radio Resource Control (RRC), service data adaptation protocol (SDAP), Packet Data Convergence Protocol (PDCP)). The CU 160 (e.g., one or more CUs) may be connected to a DU 165 (e.g., one or more DUs) or an RU 170 (e.g., one or more RUs), or some combination thereof, and the DUs 165, RUs 170, or both may host lower protocol layers, such as layer 1 (L1) (e.g., physical (PHY) layer) or L2 (e.g., radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (e.g., via one or multiple different RUs, such as an RU 170). In some cases, a functional split between a CU 160 and a DU 165 or between a DU 165 and an RU 170 may be within a protocol layer (e.g., some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to a DU 165 via a midhaul communication link 162 (e.g., F1, F1-c, F1-u), and a DU 165 may be connected to an RU 170 via a fronthaul communication link 168 (e.g., open fronthaul (FH) interface). In some examples, a midhaul communication link 162 or a fronthaul communication link 168 may be implemented in accordance with an interface (e.g., a channel) between layers of a protocol stack supported by respective network entities (e.g., one or more of the network entities 105) that are in communication via such communication links.

In some wireless communications systems (e.g., the wireless communications system 100), infrastructure and spectral resources for radio access may support wireless backhaul link capabilities to supplement wired backhaul connections, providing an IAB network architecture (e.g., to a core network 130). In some cases, in an IAB network, one or more of the network entities 105 (e.g., network entities 105 or IAB node(s) 104) may be partially controlled by each other. The IAB node(s) 104 may be referred to as a donor entity or an IAB donor. A DU 165 or an RU 170 may be partially controlled by a CU 160 associated with a network entity 105 or base station 140 (such as a donor network entity or a donor base station). The one or more donor entities (e.g., IAB donors) may be in communication with one or more additional devices (e.g., IAB node(s) 104) via supported access and backhaul links (e.g., backhaul communication link(s) 120). IAB node(s) 104 may include an IAB mobile termination (IAB-MT) controlled (e.g., scheduled) by one or more DUs (e.g., DUs 165) of a coupled IAB donor. An IAB-MT may be equipped with an independent set of antennas for relay of communications with UEs 115 or may share the same antennas (e.g., of an RU 170) of IAB node(s) 104 used for access via the DU 165 of the IAB node(s) 104 (e.g., referred to as virtual IAB-MT (vIAB-MT)). In some examples, the IAB node(s) 104 may include one or more DUs (e.g., DUs 165) that support communication links with additional entities (e.g., IAB node(s) 104, UEs 115) within the relay chain or configuration of the access network (e.g., downstream). In such cases, one or more components of the disaggregated RAN architecture (e.g., the IAB node(s) 104 or components of the IAB node(s) 104) may be configured to operate according to the techniques described herein.

In the case of the techniques described herein applied in the context of a disaggregated RAN architecture, one or more components of the disaggregated RAN architecture may be configured to support test as described herein. For example, some operations described as being performed by a UE 115 or a network entity 105 (e.g., a base station 140) may additionally, or alternatively, be performed by one or more components of the disaggregated RAN architecture (e.g., components such as an IAB node, a DU 165, a CU 160, an RU 170, an RIC 175, an SMO system 180).

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a tablet computer, a laptop computer, or a personal computer. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, vehicles, or meters, among other examples.

The UEs 115 described herein may be able to communicate with various types of devices, such as UEs 115 that may sometimes operate as relays, as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via the communication link(s) 125 (e.g., one or more access links) using resources associated with one or more carriers. The term “carrier” may refer to a set of RF spectrum resources having a defined PHY layer structure for supporting the communication link(s) 125. For example, a carrier used for the communication link(s) 125 may include a portion of an RF spectrum band (e.g., a bandwidth part (BWP)) that is operated according to one or more PHY layer channels for a given RAT (e.g., LTE, LTE-A, LTE-A Pro, NR). Each PHY layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (e.g., entity, sub-entity) of a network entity 105. For example, the terms “transmitting,” “receiving,” or “communicating,” when referring to a network entity 105, may refer to any portion of a network entity 105 (e.g., a base station 140, a CU 160, a DU 165, a RU 170) of a RAN communicating with another device (e.g., directly or via one or more other network entities, such as one or more of the network entities 105).

Signal waveforms transmitted via a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (e.g., a duration of one modulation symbol) and one subcarrier, in which case the symbol period and subcarrier spacing may be inversely related. The quantity of bits carried by each resource element may depend on the modulation scheme (e.g., the order of the modulation scheme, the coding rate of the modulation scheme, or both), such that a relatively higher quantity of resource elements (e.g., in a transmission duration) and a relatively higher order of a modulation scheme may correspond to a relatively higher rate of communication. A wireless communications resource may refer to a combination of an RF spectrum resource, a time resource, and a spatial resource (e.g., a spatial layer, a beam), and the use of multiple spatial resources may increase the data rate or data integrity for communications with a UE 115.

The time intervals for the network entities 105 or the UEs 115 may be expressed in multiples of a basic time unit which may, for example, refer to a sampling period of Tₛ=1/(Δfₘₐₓ·N_{f}) seconds, for which Δfₘₐₓ may represent a supported subcarrier spacing, and N_{f} may represent a supported discrete Fourier transform (DFT) size. Time intervals of a communications resource may be organized according to radio frames each having a specified duration (e.g., 10 milliseconds (ms)). Each radio frame may be identified by a system frame number (SFN) (e.g., ranging from 0 to 1023).

Each frame may include multiple consecutively numbered subframes or slots, and each subframe or slot may have the same duration. In some examples, a frame may be divided (e.g., in the time domain) into subframes, and each subframe may be further divided into a quantity of slots. Alternatively, each frame may include a variable quantity of slots, and the quantity of slots may depend on subcarrier spacing. Each slot may include a quantity of symbol periods (e.g., depending on the length of the cyclic prefix prepended to each symbol period). In some wireless communications systems, such as the wireless communications system 100, a slot may further be divided into multiple mini-slots associated with one or more symbols. Excluding the cyclic prefix, each symbol period may be associated with one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some examples, the TTI duration (e.g., a quantity of symbol periods in a TTI) may be variable. Additionally, or alternatively, the smallest scheduling unit of the wireless communications system 100 may be dynamically selected (e.g., in bursts of shortened TTIs (STTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a set of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (e.g., control channel elements (CCEs)) associated with encoded information for a control information format having a given payload size. Search space sets may include common search space sets configured for sending control information to UEs 115 (e.g., one or more UEs) or may include UE-specific search space sets for sending control information to a UE 115 (e.g., a specific UE).

In some examples, a network entity 105 (e.g., a base station 140, an RU 170) may be movable and therefore provide communication coverage for a moving coverage area, such as the coverage area 110. In some examples, coverage areas 110 (e.g., different coverage areas) associated with different technologies may overlap, but the coverage areas 110 (e.g., different coverage areas) may be supported by the same network entity (e.g., a network entity 105). In some other examples, overlapping coverage areas, such as a coverage area 110, associated with different technologies may be supported by different network entities (e.g., the network entities 105). The wireless communications system 100 may include, for example, a heterogeneous network in which different types of the network entities 105 support communications for coverage areas 110 (e.g., different coverage areas) using the same or different RATs.

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some examples, a UE 115 may be configured to support communicating directly with other UEs (e.g., one or more of the UEs 115) via a device-to-device (D2D) communication link, such as a D2D communication link 135 (e.g., in accordance with a peer-to-peer (P2P), D2D, or sidelink protocol). In some examples, one or more UEs 115 of a group that are performing D2D communications may be within the coverage area 110 of a network entity 105 (e.g., a base station 140, an RU 170), which may support aspects of such D2D communications being configured by (e.g., scheduled by) the network entity 105. In some examples, one or more UEs 115 of such a group may be outside the coverage area 110 of a network entity 105 or may be otherwise unable to or not configured to receive transmissions from a network entity 105. In some examples, groups of the UEs 115 communicating via D2D communications may support a one-to-many (1: M) system in which each UE 115 transmits to one or more of the UEs 115 in the group. In some examples, a network entity 105 may facilitate the scheduling of resources for D2D communications. In some other examples, D2D communications may be carried out between the UEs 115 without an involvement of a network entity 105.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (e.g., base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communications using UHF waves may be associated with smaller antennas and shorter ranges (e.g., less than one hundred kilometers) compared to communications using the smaller frequencies and longer waves of the high frequency (HF) or very high frequency (VHF) portion of the spectrum below 300 MHz.

The wireless communications system 100 may utilize both licensed and unlicensed RF spectrum bands. For example, the wireless communications system 100 may employ License Assisted Access (LAA), LTE-Unlicensed (LTE-U) RAT, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some examples, operations using unlicensed bands may be based on a carrier aggregation configuration in conjunction with component carriers operating using a licensed band (e.g., LAA). Operations using unlicensed spectrum may include downlink transmissions, uplink transmissions, P2P transmissions, or D2D transmissions, among other examples.

A network entity 105 (e.g., a base station 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

Beamforming, which may also be referred to as spatial filtering, directional transmission, or directional reception, is a signal processing technique that may be used at a transmitting device or a receiving device (e.g., a network entity 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

The UEs 115 and the network entities 105 may support retransmissions of data to increase the likelihood that data is received successfully. Hybrid automatic repeat request (HARQ) feedback is one technique for increasing the likelihood that data is received correctly via a communication link (e.g., the communication link(s) 125, a D2D communication link 135). HARQ may include a combination of error detection (e.g., using a cyclic redundancy check (CRC)), forward error correction (FEC), and retransmission (e.g., automatic repeat request (ARQ)). HARQ may improve throughput at the MAC layer in relatively poor radio conditions (e.g., low signal-to-noise conditions). In some examples, a device may support same-slot HARQ feedback, in which case the device may provide HARQ feedback in a specific slot for data received via a previous symbol in the slot. In some other examples, the device may provide HARQ feedback in a subsequent slot, or according to some other time interval.

In some examples of wireless communications system 100, a wireless device (e.g., a UE 115 or network entity 105) may operate in accordance with LDPC decoding to increase the reliability of the wireless device successfully decoding a received wireless message. Additionally, the wireless device may operate in accordance with an intelligent decoder scheme for a reduction of power consumption associated with LDPC decoding. For example, the intelligent decoder scheme may implement a machine learning classification algorithm for selection of different fixed point quantizations within the LDPC decoder. The intelligent decoder scheme reduces LDPC power by determining the quantization (e.g., LLR bit-width) per LDPC decoding iteration. For example, the wireless device may train a neural network model, which may be stored on the wireless device or stored elsewhere but accessible by the wireless device, which predicts the quantization per iteration of LDPC decoding prior to entering LDPC decoder. In some examples, the neural network model classifies code block of received data to numerous classes and selects the LDPC quantization per iteration. Each class represents lower bit quantization (e.g., 2-bits, 4-bits, or 6-bits) with all possible combinations to reduce power consumption at the LDPC decoder. Additionally, or alternatively, the neural network model may implement LDPC success predictor (e.g., suggests whether to enter LDPC), thus saving entire LDPC decoder power in cases where LDPC decoding success is determined to be below a configured threshold. By reducing the LLR bit-width associated with one or more iterations of LDPC decoding, the wireless device may reduce power expenditure associated with generating LLRs at the LDPC decoder. Additionally, due to the neural network model generating a predicted class of LDPC quantization values based on varying channel conditions, the neural network model may reduce the bit-width associated with LLRs while maintaining performance of the LDPC decoder above a performance threshold. As such, the wireless device may reduce power expenditure while maintaining communication quality.

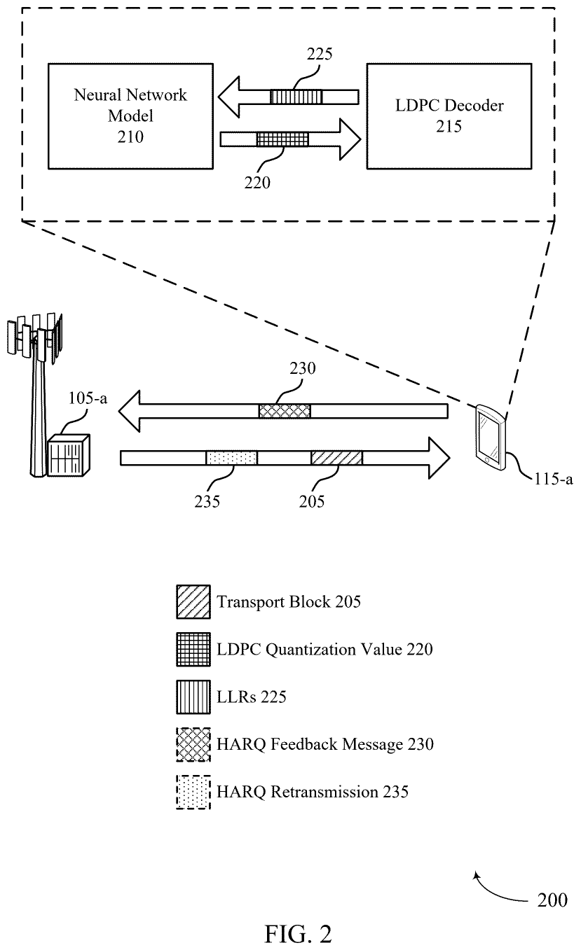

FIG. 2 shows an example of a wireless communications system 200 that supports machine learning based adaptive quantization for LDPC in accordance with one or more aspects of the present disclosure. The wireless communications system 200 may implement or may be implemented by aspects of the wireless communications system 100. For example, the wireless communications system 200 may include a UE 115-a and a network entity 105-a, which may be respective examples of a UE 115 and a network entity 105 as described herein. In some examples, the UE 115-a may receive a transport block 205 from the network entity 105-a, where the transport block 205 includes one or more code blocks of data. As such, the UE 115-a may operate in accordance with techniques described herein to perform LDPC decoding of the one or more code blocks in accordance with machine learning techniques to reduce power associated with decoding. Additionally, while the techniques described herein are with reference to the UE 115-a performing the LDPC decoding techniques, it is understood that any of the wireless devices described with reference to FIG. 1 may implement and perform the techniques described herein.

As illustrated in FIG. 2, the UE 115-a may receive a transport block 205 from the network entity 105-a. In some examples, the transport block 205 may be a unit of data that the UE 115-a receives over an air interface, where a payload included in the transport block 205, or a code block of one or more code blocks of the transport block 205, comes from higher layers (e.g., the MAC layer) and is passed to the physical layer for transmission by the network entity 105-a. In some examples, a size of the transport block 205 may vary depending on the channel conditions, the bandwidth associated with the transmission, and a modulation and coding scheme (MCS) that the network entity 105-a and UE 115-a are associated with. Additionally, the transport block 205 may include one or more of code blocks, which may be a smaller segment of the transport block 205 such that when the size of the transport block 205 exceeds a size threshold, the transport block 205 may be divided into multiple code blocks for more efficient error correction and retransmission. In some examples, the division of a transport block 205 into code blocks may facilitate the application of error correction techniques, such as LDPC coding. That is, the network entity 105-a may encode each code block separately and the UE 115-a may decode each code block separately. As such, if the UE 115-a is unable to decode a subset of code blocks in the transport block 205, the UE 115-a may request retransmission of the subset of code blocks rather than the entire transport block 205, which may reduce signaling overhead and energy expenditure.

In response to receiving the transport block 205, the UE 115-a may separately perform decoding for each of the code blocks included in the transport block 205. That is, if the transport block 205 includes multiple code blocks, the UE 115-a may perform a respective decoding procedure for each of the multiple code blocks. In some examples, the UE 115-a may perform decoding in accordance with an LDPC decoding procedure (e.g., using an LDPC decoder 215 at the UE 115-a). For example, LDPC codes may be linear error-correcting codes characterized by a sparse parity-check matrix (e.g., a matrix with a quantity of non-zero elements below a threshold). As such, the sparseness of the parity-check matrix may increase the efficiency of LDPC codes for encoding and decoding large quantities of data. In examples of LDPC encoding, the network entity 105-a may encode the data of a given code block to generate a codeword associated with the given code block. In some examples, the codeword may include both an initial set of data bits for the code block and additional parity bits, where the additional parity bits may assist in detecting and correcting errors during transmission.

Based on receiving an LDPC encoded code block, the UE 115-a may operate in accordance with LDPC decoding to reconstruct the initial set of data bits by correcting any errors that may have occurred during transmission over a channel. In some examples, LDPC decoding may use an iterative procedure to correct errors. For instance, the LDPC decoder 215 at the UE 115-a may obtain a noisy version of the transmitted codeword, where each bit in the received codeword is associated with an LLR 225 indicating likelihood that a determined value for a given bit is correct. For instance, an LLR 225 quantifies the likelihood that a received bit is either a value of 0 or a value of 1. Specifically, the LLR 225 for a received bit is the logarithm of the ratio of the probability that the bit is a 1 to the probability that the bit is a 0. That is, the LLR 225 for a bit y, where y is the received signal at decoder input after channel and noise estimators are applied to reduce or mitigate channel impairments, may be defined in accordance with Equation 1:

$$LLR ( y ) = log ( \frac{P ( y received as 1 )}{P ( y received as 0 )} ) \qquad ( 1 )$$

where P(y received as 1) is a probability determined by the UE 115-a that the bit y is a value of 1 and P(y received as 0) is a probability determined by the UE 115-a that the bit y is a value of 0. In accordance with Equation 1, a positive LLR 225 indicates that bit y is more likely a value of 1, a negative LLR 225 indicates that bit y is more likely a value of 0, and a magnitude of the LLR 225 reflects the confidence of the decision.

In some cases, the LDPC decoder 215 may iteratively update the LLR 225 for each bit of the codeword based on the relationships defined by the parity-check matrix associated with the transmitted codeword. The LDPC decoder 215 may use parity-check equations to adjust the LLRs 225 of the bits being correct. After a defined quantity of iterations, the iterative procedure converges, such that the LDPC decoder 215 makes a final decision on the value of each bit for the codeword (e.g., whether each bit is a 0 or a 1). As such, the LDPC decoder 215 may output the corrected codeword, which the UE 115-a may convert back to the initial set of data bits of the code block.

In some cases, during each iteration of LDPC decoding the LDPC decoder 215 updates the LLRs 225 for a code block. For instance, such updates may involve adding, subtracting, or averaging values based on the incoming messages from neighboring nodes in a Tanner graph generated at the UE 115-a (e.g., a bipartite graph representing the LDPC code). However, due to finite resources in hardware of the UE 115-a, these LLRs 225 may be represented in fixed-point format rather than floating-point. For example, an LLR 225 might be quantized to a 6-bit or 8-bit representation (e.g., an LDPC quantization value), where the total quantity of bits includes both integer and fractional parts of the LLR 225. That is, after each iteration of the LDPC decoding procedure, the updated LLRs 225 are quantized in accordance with the LDPC quantization value, where the updated LLRs 225 are rounded to the nearest representable value within the chosen bit-width. By limiting the LLRs 225 to a predefined range, the UE 115-a may prevent overflow. For example, if the LLR 225 range is set from −7 to +7 in a 4-bit representation, any value outside this range is clipped.

In some cases, however, LDPC decoding procedure may be associated with large power consumption within a modem of the UE 115-a. For example, as the LDPC quantization value 220 (e.g., LLR bit-width) associated with each LLR 225 iteration increases, the complexity of LDPC decoding and the power consumption may increase. Additionally, each LLR 225 may be derived from channel parameters associated with receiving a given code block (e.g., SNR, Delay or Doppler Spread, power delay profile (PDP), or other noises associated with physical channel transmission). As such, different levels of channel quality may allow for different LDPC quantization values 220 (e.g., different LLR 225 bit widths) without impacting performance of the LDPC decoder 215. For example, if the SNR for a channel associated with a first code block is above an SNR threshold, the LDPC decoder 215 may be able to decode the first code block in accordance with a lower LDPC quantization value 220 (e.g., each LLR 225 is clipped to 2-bits, rather than 6-bits or 8-bits). If, however, the SNR for the channel is below the SNR threshold, the LDPC decoder 215 may decode the first code block in accordance with a higher LDPC quantization value 220 (e.g., each LLR 225 is clipped to 6-bits or 8-bits due to LLR 225 confidence being lower). In some legacy approaches of LDPC decoding, the LDPC input to the LDPC decoder 215 may be quantized to a fixed 6-bit for each LLR, with an internal LDPC quantization of a fixed 8-bit for each LLR 225. As such, it may be advantageous for the UE 115-a to analyze channel quality metrics associated with receiving the transport block 205 to determine scenarios in which LDPC quantization may be reduced while retaining LDPC decoding performance.

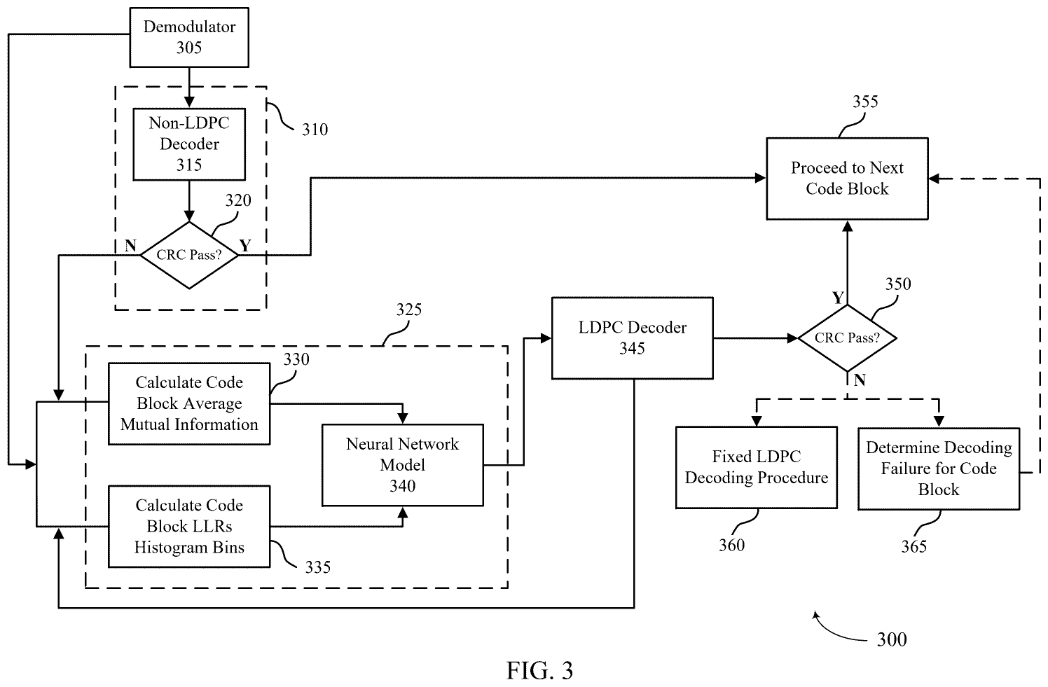

According to the techniques described herein, the UE 115-a may operate in accordance with an intelligent decoder design for LDPC quantization power reduction by implementing a machine learning classification algorithm for selection of different fixed point LDPC quantization values 220 within the LDPC decoder 215. For example, as illustrated in FIG. 2, the UE 115-a may include a neural network model 210 which may predict the LDPC quantization value 220 associated with each LLR 225 for a code block per iteration, prior to entering the LDPC decoder. For instance, the neural network model 210 may classify each code block to a quantity of classes that choose the LDPC quantization value 220 per each iteration of LDPC decoding. In some examples, each class of the quantity of classes may represent a lower bit quantization compared to legacy approaches of LDPC decoding (e.g., 2-bits, 4-bits, 6-bits, or 8-bits) with all possible combinations to reduce power consumption at the LDPC decoder 215. As such, for a given iteration of LDPC decoding, the neural network model 210 may output to the LDPC decoder 215 an LDPC quantization value 220 to use in accordance with generating the LLRs 225 for a given LDPC iteration. In some examples, the neural network model 210 may use the LLRs 225 generated by the LDPC decoder 215 from a given iteration to determine the LDPC quantization value 220 for a subsequent round of LDPC decoding. For example, after a first iteration of LDPC decoding for a first code block, the LDPC decoder 215 may output to the neural network model 210 the LLRs 225 generated at the LDPC decoder 215. As such, the neural network model 210 may use mutual information associated with LLRs 225 from the first iteration to determine a LDPC quantization value 220 for the second iteration of LDPC decoding for output to the LDPC decoder 215. Further discussion of LDPC decoding iterations are described herein, including with reference to FIG. 3.

In some examples, the LDPC decoder 215 may determine to stop iterations of LDPC decoding for the first code block if the LDPC decoder 215 determines that a given iteration passes a CRC. For example, CRC is an error-detection technique that generates a fixed-size check value (e.g., CRC code) based on the data. In some examples, the network entity 105-a may append a respective CRC code to each code block of the transport block 205 prior to transmission. As such, the UE 115-a may perform a CRC calculation, where the result is compared with the received CRC for the code block. If the values match, the data is assumed to be error-free resulting in a CRC pass; otherwise, if errors are detected then the UE 115-a may determine a CRC fail. After each iteration of LDPC decoding, the LDPC decoder 215 may perform a CRC for the decoding iteration. If the LDPC decoder 215 determines a CRC pass, the UE 115-a may move onto decoding a subsequent code block of the transport block 205. If the LDPC decoder 215 determines a CRC fail, the LDPC decoder 215 may output the LLRs 225 to the neural network model 210 and perform a subsequent iteration of LDPC decoding in accordance with the LDPC quantization value 220 indicated by the neural network model 210. Further discussion of the techniques associated with neural network model 210 are described herein, including with reference to FIG. 3.

In some cases, the UE 115-a may be defined or configured with a threshold quantity of LDPC decoding iterations. As such, if the quantity of iterations of LDPC decoding for a given code block satisfies the threshold, the UE 115-a may determine decoding failure of the given code block and determine to perform a secondary decoding procedure. In a first example of a secondary decoding procedure, the UE 115-a may determine to reperform LDPC decoding in accordance with the fixed point legacy LDPC approach. In a second example of the secondary decoding procedure, the UE 115-a may determine failure of the given code block and proceed to a subsequent code block of the transport block 205. In a third example of the secondary decoding procedure, the UE 115-a may determine failure of the given code block and terminate (e.g., refrain from) decoding of additional code blocks in the transport block 205. Further discussion of the various secondary decoding procedures are described herein, including with reference to FIG. 3.

In accordance with performing LDPC decoding for one or more code blocks of the transport block 205, the UE 115-a may transmit HARQ feedback message 230. For example, the HARQ feedback message 230 may indicate an acknowledgment (ACK) if the UE 115-a is able to successfully decode each code block of the transport block 205. If the UE 115-a is unable to decode one or more of the code blocks of the transport block 205, the UE 115-a may indicate a negative-ACK (NACK). In some examples of transmitting the NACK, the HARQ feedback message 230 may request the network entity 105-a to retransmit the entire transport block 205. In some other examples of transmitting the NACK, the HARQ feedback message 230 may request the network entity 105-a to retransmit the one or more code blocks of the transport block 205 that the UE 115-a is unable to decode (e.g., rather than the entire transport block 205). In response to receiving the HARQ feedback message 230, the network entity 105-a may determine that the transport block 205 was successfully decoded by the UE 115-a (e.g., in cases of ACK indication), or determine to transmit a HARQ retransmission 235 (e.g., in cases of NACK indication). As such, the HARQ retransmission 235 may include the entire transport block 205 or may include the one or more code blocks indicated by the UE 115-a in the HARQ feedback message 230.

FIG. 3 shows an example of a machine learning based decoding procedure 300 that supports machine learning based adaptive quantization for LDPC in accordance with one or more aspects of the present disclosure. The machine learning based decoding procedure 300 may implement or may be implemented by aspects of the wireless communications system 100 and 200. For example, the machine learning based decoding procedure 300 may be implemented by the UE 115-a as described with reference to FIG. 2. In some examples, a UE 115 may operate in accordance with an intelligent decoding scheme 325 which includes a neural network model 340, which may be an example of the neural network model 210 as described with reference to FIG. 2. Additionally, the LDPC decoder 345 may be an example of the LDPC decoder 215 as described with reference to FIG. 2. Additionally, or alternatively, while examples described in FIG. 3 reference techniques performed by a UE 115, it is understood that the techniques of machine learning based decoding procedure 300 may be implemented by any wireless device described with reference to FIG. 1.

As illustrated in FIG. 3, the UE 115 may include a demodulator 305. For example, the UE 115 may receive one or more code blocks (e.g., included in transport block 205) and respectively demodulate each of the one or more code blocks using the demodulator 305. In some examples, the demodulator 305 may perform demodulation of received wireless messages, which involves converting a radio frequency signal received by the antenna of the UE 115 into a digital data stream. An example of the UE 115 demodulating a first code block is described in accordance with the techniques of FIG. 3.

Based on the demodulating the first code block, the demodulator 305 may output a set of LLRs, where each LLR of the set of LLRs is associated with a respective bit of the set of bits included in the first code block. In some examples, the LLRs output from the demodulator 305 may be associated with a first LLR bit-width corresponding to an LDPC quantization value. In some examples, the first LLR bit-width may be associated with a legacy fixed quantization value for LDPC decoding (e.g., 6-bits).

In some examples, prior to LDPC decoding, the demodulator 305 may optionally attempt to decode the first code block in accordance with a non-LDPC decoding scheme 310, which includes a non-LDPC decoder 315. For example, the non-LDPC decoder 315 may be an example of a polar code decoder, a turbo code decoder, a convolutional code decoder, a Reed-Solomon code decoder, a Bose-Chaudhuri-Hocquenghem (BCH) decoder, a tail-biting convolutional code (TBCC) decoder, a reference signal polar code decoder, among other examples.

At 320, the UE 115 may determine whether decoding the first code block results in a CRC pass based on performing one or more decoding attempts at the non-LDPC decoder 315. If the decoding results in a CRC pass, then the UE 115 may proceed to demodulating and decoding a second code block of the received transport block (e.g., at 355).

If the non-LDPC decoding scheme 310 results in a CRC fail, then the UE 115 may proceed to performing LDPC decoding in accordance with an intelligent decoding scheme 325. As described herein, the non-LDPC decoding scheme 310 may be optional, such that the UE 115 may proceed to the performing the intelligent decoding scheme 325 directly after demodulating the first code block.

As illustrated in FIG. 3, the UE 115 may input information associated with the LLRs of the first code block into the neural network model 340. For example, the input information may include average mutual information of the LLRs output from the demodulator 305 that are associated with the first code block. The input information may also include bins of a histogram of the mutual information of the LLRs associated with the first code block.

In some examples, at 330, the UE 115 may calculate code block average mutual information by calculating the average mutual information associated with the LLRs of the first code block. In some examples, the UE 115 may calculate the average mutual information in accordance with Equation 2:

$${\sum }_{i} {P}_{i} {log}_{2} ( 2 {P}_{i} ) + ( 1 - {P}_{i} ) {log}_{2} ( 2 ( 1 - {P}_{i} ) ) , {P}_{i} = \frac{1}{1 + exp ( {LLR}_{i} )} \qquad ( 2 )$$

In Equation 2, the subscript i represents the index of the received LLRs within a code block. A single code block, at this stage of the decoder, consists of a stream of values, and each value at index i is referred as an LLR for the respective index i. LLR is a Logarithmic representation of priori information of bit probabilities received from the channel and measures the likelihood of a received signal being a bit of 0 or 1. The LLR is a logarithmic measure derived from the probabilities, as shown by Equation 1 above and Pᵢ represents the probability of the received signal bit being ‘0’ or ‘1’. Thus, Pᵢ represents the probability, but in terms of LLR. An example of the mutual information described herein, which may be expressed as I(x,y), is shown by Equation 3 below:

$$I ( x , y ) = \frac{1}{N} {\sum }_{i = 0}^{N - 1} p ( 0 \vert {y}_{i} ) {log}_{2} ( 2 p ( 0 \vert {y}_{i} ) ) + p ( 1 \vert {y}_{i} ) {log}_{2} ( 2 p ( 1 \vert {y}_{i} ) ) \qquad ( 3 )$$

In Equation 3, x is the transmitted “true” signal, which includes one or more binary bits (e.g., bits that have a value of ‘0’ or ‘1’).

In some examples, at 335, the UE 115 may calculate code block LLRs histogram bins by calculating a histogram of the mutual information associated with the LLRs. For example, the histogram may include a quantity of bins (e.g., 32 bins), where each bin of the quantity of bins indicates information for the LLRs associated with first code block.

In accordance with performing the techniques at 330 and 335, the UE 115 may input both the average mutual information associated with the LLRs and the histogram associated with the LLRs into the neural network model 340. As such, the neural network model 340 may output one or more parameters associated with LDPC decoding based on the input parameters and based on the UE 115 training the neural network model 340 prior to demodulating the first code block.

In some examples, the neural network model 340 is trained across multiple channel qualities and multiple MCSs (e.g., multiple SNR values and MCSs of a channel), where each MCS-SNR combination is associated with a set of classes, and where each class is associated with a different set of LDPC quantization values for a set of LDPC iterations. For example, assume that the UE 115 tests first MCS-SNR combination on four classes, where a first class indicates a quantization value of 4-bits for each of a set of four LDPC decoding iterations (e.g., [4,4,4,4]), a second class indicates 4-bits for a first iteration, 6-bits for a second iteration, and 4-bits for a third and fourth iteration (e.g., [4,6,4,4]), a third class indicates a quantization value of 6-bits followed by 8-bits for subsequent LDPC decoding iterations in accordance with legacy fixed LDPC decoding procedures (e.g., [6,8,8,8]), and a fourth class that indicates that the likelihood of successful decoding based on the SNR value is below a threshold (e.g., [−1]). As such, the neural network model 340 may determine which of the four classes results in highest power savings while maintaining LDPC decoding performance above a performance threshold. That is, the neural network model 340 selects a given class based on the maximal power savings per quantity of classes out of the minimal power savings within the different scenarios in accordance with a minimal performance impact threshold. In some examples, the UE 115 may train the neural network model 340 using multiple classes with a defined quantity of iterations for LDPC decoding (e.g., due to exponential growth of data training). Additionally, each of the defined quantity of iterations for a class may be one of a set of defined fixed point bit-widths (e.g., 2-bits, 4-bits, 6-bits, or 8-bits).

In accordance with training the neural network model 340 and inputting the information for the LLRs associated with first code block, the neural network model 340 may output one or more parameters. In some examples, the neural network model 340 may output a class prediction of LDPC quantization per iteration. For example, the neural network model 340 may output predicted class of [4,4,4,4] indicating a LDPC quantization value of 4-bits for the LLRs for four decoding iterations at the LDPC decoder 345.

Additionally, or alternatively, the neural network model 340 may output a success prediction value where the success prediction value may indicate the likelihood of decoding the first code block. In some examples, the LDPC decoder 345 may determine to perform the decoding of the first code block based on the success prediction value being above a configured success threshold. In some examples, the LDPC decoder 345 may determine to refrain from decoding the first code block if the success prediction value is below the configured success threshold (e.g., determine a decoding failure of the first code block).

Based on outputting a predicted class, the neural network model 340 may indicate to the LDPC decoder 345 an LDPC quantization value to use per iteration of LDPC decoding. As such, the LDPC decoder 345 may operate in accordance with the LDPC quantization value indicated by the neural network model 340 for a given iteration. For instance, in the example where the predicted class output by the neural network model 340 is [4,4,4,4], the LDPC decoder 345 may generate the LLRs using a bit-width of 4-bits for the first iteration of LDPC decoding. Different values in the class (e.g., the predicted class output by the neural network model 340) may be provided, which may correspond to different LDPC quantization values for different iterations.

After performing a given iteration of the LDPC decoding, the LDPC decoder 345 may determine if the given iteration results in an CRC pass (e.g., at 350). If a given iteration of LDPC decoding results in CRC pass, then the UE 115 may proceed to decoding the next code block of the received transport block (e.g., at 355). If a given iteration of the LDPC decoding results in CRC fail, then the LDPC decoder 345 may proceed to a subsequent iteration of LDPC decoding. For instance, if the first iteration results in CRC fail, the LDPC decoder 345 may perform a second iteration of LDPC decoding.

In some examples, the LDPC decoder 345 may perform the second iteration in accordance with the second index of the predicted class output by the neural network model 340. That is, if the predicted class is [4,4,4,4], then for the second iteration the LDPC decoder 345 may output LLRs with a bit-width of 4-bits based on the second index indicating an LDPC quantization value of 4.

In some other examples, the LDPC decoder 345 may output to the neural network model 340 the LLRs generated from the first iteration of LDPC decoding. As such, the UE 115 may calculate average mutual information and a set of bins of a histogram associated with the LLRs generated from the first iteration and input the information into the neural network model 340 (e.g., updated input information). In response to the updated input information, the neural network model 340 may output an updated predicted class, where the updated predicted class may indicate an LDPC quantization value for a second iteration of LDPC decoding. That is, the LDPC quantization value for the second iteration may be based on the LLRs the LDPC decoder 345 generates during the first iteration. As such, the LDPC decoder 345 may perform the second iteration of LDPC decoding in accordance with the LDPC quantization value associated with the second iteration.

In accordance with the techniques of FIG. 3, the LDPC decoder 345 may go through multiple iterations of LDPC decoding in accordance with the LDPC quantization values output from neural network model 340, until a given iteration results in a CRC pass or until a threshold quantity of LDPC iterations is satisfied. For instance, in the example of FIG. 3, the threshold quantity of iterations may be four (e.g., corresponding to the quantity of iterations used in the classes for testing the neural network model 340), however, it is understood that the threshold quantity of iterations may be any integer value. As such, if the LDPC decoder 345 performs a quantity of LDPC decoding iterations that satisfies the threshold quantity of iterations (e.g., four in the example of FIG. 3), then the UE 115 may perform one or more secondary decoding procedures.

In some examples of secondary decoding procedures, the LDPC decoder 345 may determine (e.g., at 360) to perform LDPC decoding in accordance with the legacy fixed LDPC decoding procedure (e.g., a class corresponding to [6,8,8,8]).

In some examples of secondary decoding procedures, the LDPC decoder 345 may determine (e.g., at 365) a decoding failure of the first code block based on each iteration of the LDPC decoding procedure resulting in a CRC failure. If the UE 115 determines a decoding failure for the first code block, the UE 115 may proceed to decoding the next code block of the transport block (e.g., at 355) or skip the rest of the code blocks in the transport block and request retransmission from the network entity of the transport block. In some cases, the UE 115 may perform the techniques at 365 after or alternatively to the techniques at 360.

As such, the UE may perform the techniques of the machine learning based decoding procedure 300 for one or more code blocks of the received transport block. If the UE determines decoding failure for one or more code blocks of the received transport block, the UE may transmit a HARQ feedback message requesting the network entity to retransmit the one or more code blocks or the entire transport block (e.g., HARQ feedback message 230).

By reducing the LLR bit-width associated with one or more iterations of LDPC decoding, the UE 115 may reduce power expenditure associated with generating LLRs at the LDPC decoder. Additionally, due to the neural network model 340 generating a predicted class of LDPC quantization values based on the average mutual information associated with the LLRs and the histogram associated with the LLRs for one or more code blocks, whose size may vary based on channel conditions or the MCS used by the UE 115 and network entity 105, the neural network model 340 may reduce the bit-width associated LLRs while maintaining performance of the LDPC decoder 345 above a performance threshold. As such, the UE 115 may reduce power expenditure while maintaining communication quality.

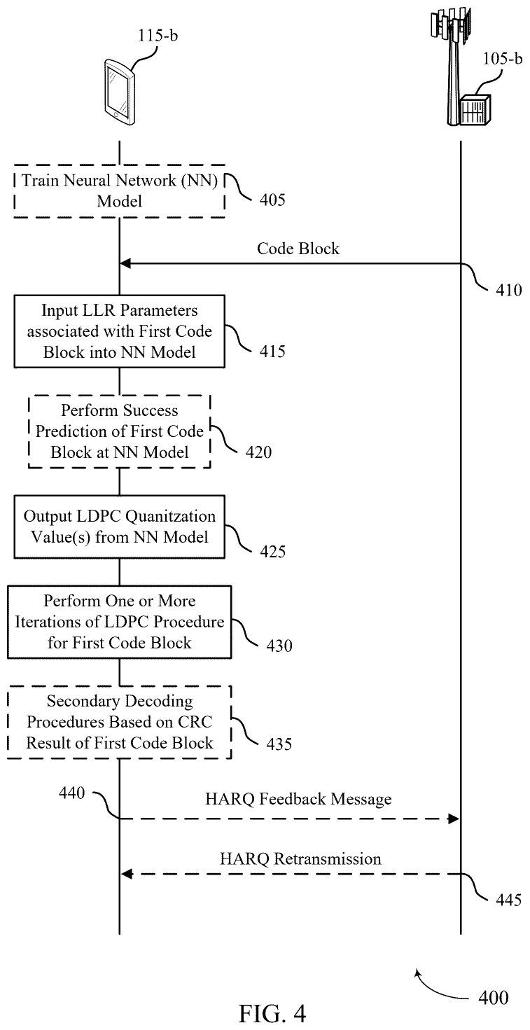

FIG. 4 shows an example of a process flow 400 that supports machine learning based adaptive quantization for LDPC in accordance with one or more aspects of the present disclosure. In some examples, process flow 400 may implement aspects of wireless communications system 100, wireless communications system 200, and machine learning based decoding procedure 300. Process flow 400 may include a UE 115-b which may be an example of a UE 115, as described with reference to FIGS. 1 through 3. Additionally, process flow 400 may include a network entity 105-b which may be an example of a network entity 105, as described with reference to FIGS. 1 through 3. Alternative examples of the following may be implemented, where some steps are performed in a different order than described or are not performed at all. In some cases, steps may include additional features not mentioned below, or further steps may be added. In addition, it is understood that these processes may occur between any quantity of network devices and network device types.

At 405, the UE 115-b may train a neural network model (e.g., neural network model 210 or neural network model 340, as described with reference to FIGS. 2 and 3). For example, the UE 115-b may train, prior to outputting a set of LDPC quantization values, the neural network model in accordance with a multi-class classification. In some examples, each class of a set of classes associated with the multi-class classification may indicate one or more allowed LDPC quantizations values for each respective iteration of a set of LDPC decoding iterations.

At 410, the UE 115-b may receive from the network entity 105-b a first code block of one or more code blocks associated with a transport block for the UE 115-b.

At 415, the UE 115-b may input into the neural network model, a set of input parameters. For example, the set of input parameters may include at least mutual information of a set of LLRs associated with demodulating the first code block and a histogram associated with the set of LLRs associated with demodulating the first code block. Additionally, the set of LDPC quantization values output from the neural network model may be based on the set of input parameters. In some examples, each respective LDPC quantization value of the set of LDPC quantization values may be associated with a respective set of input parameters and a given LDPC quantization value may be based on a previous iteration of LLRs output from an LDPC decoder that performs the LDPC decoding procedure.

At 420, the UE 115-b may optionally perform at the neural network model, a first iteration of a prediction procedure that outputs a first LDPC success prediction value associated with decoding the first code block. In some examples, the UE 115-b may perform one or more iterations of the LDPC decoding procedure for the first code block based on the first LDPC success prediction value satisfying a prediction value threshold. Additionally, or alternatively, the neural network model may perform a second iteration of the prediction procedure that outputs a second LDPC success prediction value associated with decoding a second code block of the one or more code blocks. If the second LDPC success prediction value does not satisfy the prediction value threshold, the UE 115-b may refrain from performing a second LDPC decoding procedure for the second code block.

The success prediction values may be output by the neural network model. For instance, during the neural network training process, the network may determine a mapping between the input LLRs to a probability of decoding or detection success (or failure). If the neural network prediction indicates that the current code block will pass CRC, then the neural network outputs a quantization configuration per iteration to use (e.g., other classes of the network). If the neural network prediction indicates that the current code block will fail CRC, then the neural network outputs a value “Success Predictor” class (e.g., and a success prediction value).

The neural network outputs are the different quantization mentioned herein, and another class referred to as “Success Predictor,” which is orthogonal to the other classes (e.g., from all the classes, only one is selected as an output, either the Success Predictor or a single quantization configuration per iteration).

During inference, the neural network receives the input LLRs, and based on the trained model, the neural network determines to proceed with the decoding (and with what Quantization configuration per iteration), or determines to skip the detection of the current code block (if the Success Predictor class was chosen from the neural network). The Success Predictor has a potential power reduction gain because if correct, the entire LDPC decoding for the current code block is not performed.

For example, the differentiation of the power reduction when choosing a better quantization scheme (using 4 bits instead of 8 bits at some iteration) is still less of a power reduction compared to not even trying to decode at all (using 0 instead of 8 bits at some iteration).

At 425, the UE 115-b may output using the neural network model, the set of LDPC quantization values for the set of iterations of an LDPC decoding procedure for the first code block. In some examples, the set of LDPC quantization values may include respective LDPC quantization values for respective iterations of the set of iterations. In some examples, the neural network model outputs the set of LDPC quantization values for the set of iterations of the LDPC decoding procedure for the first code block to an LDPC decoder associated with the UE 115-b (e.g., LDPC decoder 215 or LDPC decoder 345 as described with reference to FIGS. 2 and 3). In some examples, each respective LDPC quantization value indicates a respective quantity of bits for each LLR of a set of LLRs for the first code block.

At 430, the UE 115-b may perform one or more iterations of the LDPC decoding procedure for the first code block in accordance with one or more LDPC quantization values of the set of LDPC quantization values output using the neural network model. For example, the UE 115-b may perform a first iteration of the one or more iterations in accordance with a first LDPC quantization value of the one or more LDPC quantization values. In some examples, the first iteration of the LDPC decoding procedure results in CRC failure for the first code block. In such examples, the UE 115-b may perform a second iteration of the one or more iterations in accordance with a second LDPC quantization value of the one or more LDPC quantization values. In some examples, the UE 115-b may refrain from performing additional iterations of the set of iterations of the LDPC decoding procedure for the first code block if the second iteration results in CRC pass for the first code block.

At 435, the UE 115-b may optionally perform one or more secondary decoding procedures based on the CRC result of the first code block. For example, if the first code block is successfully decoded, the UE 115-b may perform a second LDPC decoding procedure for a second code block of the one or more code blocks based on CRC pass for the first code block.

In some cases, however, each of the set of iterations of the LDPC decoding procedure may result in CRC failure for the first code block. In some examples, the UE 115-b may perform one or more additional iterations of the LDPC decoding procedure for the first code block in accordance with one or more fixed LDPC quantization values (e.g., legacy LDPC decoding), where the one or more fixed LDPC quantization values may include respective fixed LDPC quantization values for respective additional iterations. In some examples, the UE 115-b may refrain from decoding additional code blocks of the one or more code blocks based on each of the set of iterations of the LDPC decoding procedure resulting in CRC failure for the first code block.

At 440, the UE 115-b may optionally transmit a HARQ feedback message (e.g., HARQ feedback message 230, as described with reference to FIG. 2). For example, the HARQ feedback message may indicate an ACK if the UE 115-b is able to successfully decode each code block of the transport block. If the UE 115-b is unable to decode one or more of the code blocks of the transport block, the UE 115-b may indicate a NACK. In some examples of transmitting the NACK, the HARQ feedback message may request the network entity 105-b to retransmit the entire transport block. In some other examples of transmitting the NACK, the HARQ feedback message may request the network entity 105-b to retransmit the one or more code blocks of the transport block that the UE 115-b is unable to decode (e.g., rather than the entire transport block 205).

At 445, the network entity 105-b may optionally transmit a HARQ retransmission (e.g., HARQ retransmission 235 as described with reference to FIG. 2). For example, the network entity 105-b may determine to transmit HARQ retransmission in cases where the HARQ feedback message included a NACK indication. As such, the HARQ retransmission may include the entire transport block or may include the one or more code blocks indicated by the UE 115-b in the HARQ feedback message as unsuccessfully decoded.

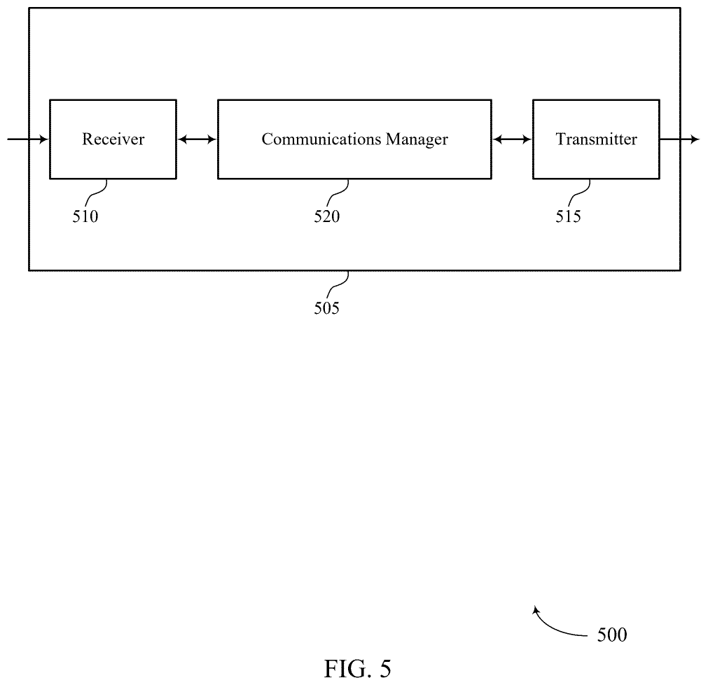

FIG. 5 shows a block diagram 500 of a device 505 that supports machine learning based adaptive quantization for LDPC in accordance with one or more aspects of the present disclosure. The device 505 may be an example of aspects of a UE 115 as described herein. The device 505 may include a receiver 510, a transmitter 515, and a communications manager 520. The device 505, or one or more components of the device 505 (e.g., the receiver 510, the transmitter 515, the communications manager 520), may include at least one processor, which may be coupled with at least one memory, to, individually or collectively, support or enable the described techniques. Each of these components may be in communication with one another (e.g., via one or more buses).

The receiver 510 may provide a means for receiving information such as packets, user data, control information, or any combination thereof associated with various information channels (e.g., control channels, data channels, information channels related to machine learning based adaptive quantization for LDPC). Information may be passed on to other components of the device 505. The receiver 510 may utilize a single antenna or a set of multiple antennas.

The transmitter 515 may provide a means for transmitting signals generated by other components of the device 505. For example, the transmitter 515 may transmit information such as packets, user data, control information, or any combination thereof associated with various information channels (e.g., control channels, data channels, information channels related to machine learning based adaptive quantization for LDPC). In some examples, the transmitter 515 may be co-located with a receiver 510 in a transceiver module. The transmitter 515 may utilize a single antenna or a set of multiple antennas.

The communications manager 520, the receiver 510, the transmitter 515, or various combinations or components thereof may be examples of means for performing various aspects of machine learning based adaptive quantization for LDPC as described herein. For example, the communications manager 520, the receiver 510, the transmitter 515, or various combinations or components thereof may be capable of performing one or more of the functions described herein.

In some examples, the communications manager 520, the receiver 510, the transmitter 515, or various combinations or components thereof may be implemented in hardware (e.g., in communications management circuitry). The hardware may include at least one of a processor, a digital signal processor (DSP), a central processing unit (CPU), an application-specific integrated circuit (ASIC), a field-programmable gate array (FPGA) or other programmable logic device, a microcontroller, discrete gate or transistor logic, discrete hardware components, or any combination thereof configured as or otherwise supporting, individually or collectively, a means for performing the functions described in the present disclosure. In some examples, at least one processor and at least one memory coupled with the at least one processor may be configured to perform one or more of the functions described herein (e.g., by one or more processors, individually or collectively, executing instructions stored in the at least one memory).

Additionally, or alternatively, the communications manager 520, the receiver 510, the transmitter 515, or various combinations or components thereof may be implemented in code (e.g., as communications management software or firmware) executed by at least one processor (e.g., referred to as a processor-executable code). If implemented in code executed by at least one processor, the functions of the communications manager 520, the receiver 510, the transmitter 515, or various combinations or components thereof may be performed by a general-purpose processor, a DSP, a CPU, an ASIC, an FPGA, a microcontroller, or any combination of these or other programmable logic devices (e.g., configured as or otherwise supporting, individually or collectively, a means for performing the functions described in the present disclosure).

In some examples, the communications manager 520 may be configured to perform various operations (e.g., receiving, obtaining, monitoring, outputting, transmitting) using or otherwise in cooperation with the receiver 510, the transmitter 515, or both. For example, the communications manager 520 may receive information from the receiver 510, send information to the transmitter 515, or be integrated in combination with the receiver 510, the transmitter 515, or both to obtain information, output information, or perform various other operations as described herein.

The communications manager 520 may support wireless communications in accordance with examples as disclosed herein. For example, the communications manager 520 is capable of, configured to, or operable to support a means for receiving a first code block of one or more code blocks associated with a transport block for the wireless device. The communications manager 520 is capable of, configured to, or operable to support a means for outputting, using a neural network model associated with the wireless device, a set of multiple LDPC quantization values for a set of multiple iterations of an LDPC decoding procedure for the first code block, where the set of multiple LDPC quantization values include respective LDPC quantization values for respective iterations of the set of multiple iterations. The communications manager 520 is capable of, configured to, or operable to support a means for performing one or more iterations of the LDPC decoding procedure for the first code block in accordance with one or more LDPC quantization values of the set of multiple LDPC quantization values output using the neural network model.

By including or configuring the communications manager 520 in accordance with examples as described herein, the device 505 (e.g., at least one processor controlling or otherwise coupled with the receiver 510, the transmitter 515, the communications manager 520, or a combination thereof) may support techniques for reduced processing, reduced power consumption, and more efficient utilization of communication resources.

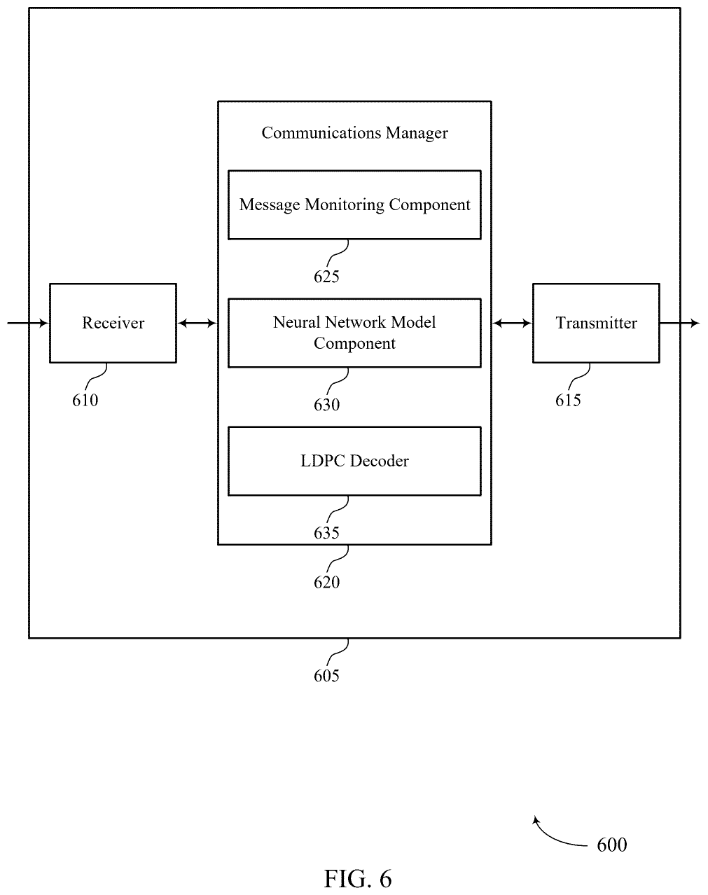

FIG. 6 shows a block diagram 600 of a device 605 that supports machine learning based adaptive quantization for LDPC in accordance with one or more aspects of the present disclosure. The device 605 may be an example of aspects of a device 505 or a UE 115 as described herein. The device 605 may include a receiver 610, a transmitter 615, and a communications manager 620. The device 605, or one or more components of the device 605 (e.g., the receiver 610, the transmitter 615, the communications manager 620), may include at least one processor, which may be coupled with at least one memory, to support the described techniques. Each of these components may be in communication with one another (e.g., via one or more buses).

The receiver 610 may provide a means for receiving information such as packets, user data, control information, or any combination thereof associated with various information channels (e.g., control channels, data channels, information channels related to machine learning based adaptive quantization for LDPC). Information may be passed on to other components of the device 605. The receiver 610 may utilize a single antenna or a set of multiple antennas.

The transmitter 615 may provide a means for transmitting signals generated by other components of the device 605. For example, the transmitter 615 may transmit information such as packets, user data, control information, or any combination thereof associated with various information channels (e.g., control channels, data channels, information channels related to machine learning based adaptive quantization for LDPC). In some examples, the transmitter 615 may be co-located with a receiver 610 in a transceiver module. The transmitter 615 may utilize a single antenna or a set of multiple antennas.

The device 605, or various components thereof, may be an example of means for performing various aspects of machine learning based adaptive quantization for LDPC as described herein. For example, the communications manager 620 may include a message monitoring component 625, a neural network model component 630, an LDPC decoder 635, or any combination thereof. The communications manager 620 may be an example of aspects of a communications manager 520 as described herein. In some examples, the communications manager 620, or various components thereof, may be configured to perform various operations (e.g., receiving, obtaining, monitoring, outputting, transmitting) using or otherwise in cooperation with the receiver 610, the transmitter 615, or both. For example, the communications manager 620 may receive information from the receiver 610, send information to the transmitter 615, or be integrated in combination with the receiver 610, the transmitter 615, or both to obtain information, output information, or perform various other operations as described herein.

The communications manager 620 may support wireless communications in accordance with examples as disclosed herein. The message monitoring component 625 is capable of, configured to, or operable to support a means for receiving a first code block of one or more code blocks associated with a transport block for the wireless device. The neural network model component 630 is capable of, configured to, or operable to support a means for outputting, using a neural network model associated with the wireless device, a set of multiple LDPC quantization values for a set of multiple iterations of an LDPC decoding procedure for the first code block, where the set of multiple LDPC quantization values include respective LDPC quantization values for respective iterations of the set of multiple iterations. The LDPC decoder 635 is capable of, configured to, or operable to support a means for performing one or more iterations of the LDPC decoding procedure for the first code block in accordance with one or more LDPC quantization values of the set of multiple LDPC quantization values output using the neural network model.

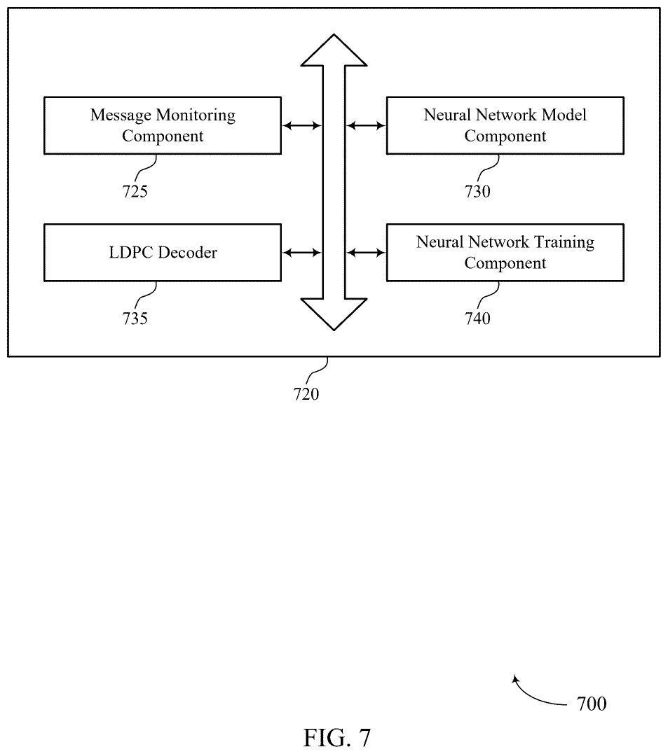

FIG. 7 shows a block diagram 700 of a communications manager 720 that supports machine learning based adaptive quantization for LDPC in accordance with one or more aspects of the present disclosure. The communications manager 720 may be an example of aspects of a communications manager 520, a communications manager 620, or both, as described herein. The communications manager 720, or various components thereof, may be an example of means for performing various aspects of machine learning based adaptive quantization for LDPC as described herein. For example, the communications manager 720 may include a message monitoring component 725, a neural network model component 730, an LDPC decoder 735, a neural network training component 740, or any combination thereof. Each of these components, or components or subcomponents thereof (e.g., one or more processors, one or more memories), may communicate, directly or indirectly, with one another (e.g., via one or more buses).

The communications manager 720 may support wireless communications in accordance with examples as disclosed herein. The message monitoring component 725 is capable of, configured to, or operable to support a means for receiving a first code block of one or more code blocks associated with a transport block for the wireless device. The neural network model component 730 is capable of, configured to, or operable to support a means for outputting, using a neural network model associated with the wireless device, a set of multiple LDPC quantization values for a set of multiple iterations of an LDPC decoding procedure for the first code block, where the set of multiple LDPC quantization values include respective LDPC quantization values for respective iterations of the set of multiple iterations. The LDPC decoder 735 is capable of, configured to, or operable to support a means for performing one or more iterations of the LDPC decoding procedure for the first code block in accordance with one or more LDPC quantization values of the set of multiple LDPC quantization values output using the neural network model.

In some examples, the neural network model component 730 is capable of, configured to, or operable to support a means for inputting, into the neural network model, a set of input parameters, where the set of input parameters includes at least mutual information of a set of multiple LLRs associated with demodulating the first code block and a histogram associated with the set of multiple LLRs associated with demodulating the first code block, and where the set of multiple LDPC quantization values output from the neural network model is based on the set of input parameters.

In some examples, each respective LDPC quantization value of the set of multiple LDPC quantization values is associated with a respective set of input parameters. In some examples, a given LDPC quantization value is based on a previous iteration of LLRs output from an LDPC decoder that performs the LDPC decoding procedure.

In some examples, to support performing the one or more iterations of the LDPC decoding procedure for the first code block, the LDPC decoder 735 is capable of, configured to, or operable to support a means for performing a first iteration of the one or more iterations in accordance with a first LDPC quantization value of the one or more LDPC quantization values.

In some examples, the first iteration of the LDPC decoding procedure results in CRC failure for the first code block, and the LDPC decoder 735 is capable of, configured to, or operable to support a means for performing a second iteration of the one or more iterations in accordance with a second LDPC quantization value of the one or more LDPC quantization values. In some examples, the first iteration of the LDPC decoding procedure results in CRC failure for the first code block, and the LDPC decoder 735 is capable of, configured to, or operable to support a means for refraining from performing additional iterations of the set of multiple iterations of the LDPC decoding procedure for the first code block based on the second iteration resulting in CRC pass for the first code block.

In some examples, the LDPC decoder 735 is capable of, configured to, or operable to support a means for performing a second LDPC decoding procedure for a second code block of the one or more code blocks based on CRC pass for the first code block.

In some examples, each of the set of multiple iterations of the LDPC decoding procedure results in CRC failure for the first code block, and the LDPC decoder 735 is capable of, configured to, or operable to support a means for performing one or more second iterations of the LDPC decoding procedure for the first code block in accordance with one or more fixed LDPC quantization values, where the one or more fixed LDPC quantization values include respective fixed LDPC quantization values for respective second iterations of the one or more second iterations.

In some examples, each of the set of multiple iterations of the LDPC decoding procedure results in CRC failure for the first code block, and the LDPC decoder 735 is capable of, configured to, or operable to support a means for refraining from decoding additional code blocks of the one or more code blocks based on each of the set of multiple iterations of the LDPC decoding procedure resulting in CRC failure for the first code block.

In some examples, the neural network model outputs the set of multiple LDPC quantization values for the set of multiple iterations of the LDPC decoding procedure for the first code block to an LDPC decoder associated with the wireless device.

In some examples, the neural network training component 740 is capable of, configured to, or operable to support a means for training, prior to outputting the set of multiple LDPC quantization values, the neural network model in accordance with a multi-class classification, where each class of a set of classes associated with the multi-class classification indicates one or more allowed LDPC quantizations values for each respective iteration of the set of multiple iterations.

In some examples, the LDPC decoder 735 is capable of, configured to, or operable to support a means for performing, prior to the LDPC decoding procedure of the first code block, a second decoding procedure for the first code block that results in an CRC failure for the first code block, where performing the one or more iterations of the LDPC decoding procedure for the first code block is based on the second decoding procedure resulting in CRC failure for the first code block.

In some examples, the neural network model component 730 is capable of, configured to, or operable to support a means for performing, at the neural network model, a first iteration of a prediction procedure that outputs a first LDPC success prediction value associated with decoding the first code block, where performing the one or more iterations of the LDPC decoding procedure for the first code block is based on the first LDPC success prediction value satisfying a prediction value threshold.

In some examples, the neural network model component 730 is capable of, configured to, or operable to support a means for performing, at the neural network model, a second iteration of the prediction procedure that outputs a second LDPC success prediction value associated with decoding a second code block of the one or more code blocks. In some examples, the LDPC decoder 735 is capable of, configured to, or operable to support a means for refraining to perform a second LDPC decoding procedure for the second code block based on the second LDPC success prediction value not satisfying the prediction value threshold.

In some examples, each respective LDPC quantization value indicates a respective quantity of bits for each LLR of a set of LLRs for the first code block.

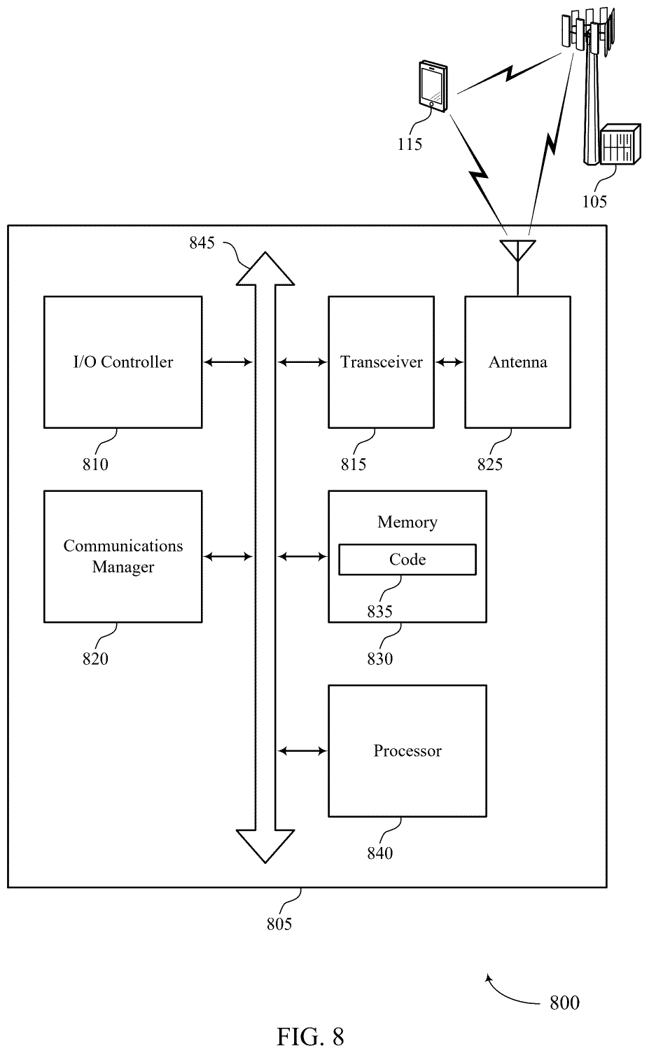

FIG. 8 shows a diagram of a system 800 including a device 805 that supports machine learning based adaptive quantization for LDPC in accordance with one or more aspects of the present disclosure. The device 805 may be an example of or include components of a device 505, a device 605, or a UE 115 as described herein. The device 805 may communicate (e.g., wirelessly) with one or more other devices (e.g., network entities 105, UEs 115, or a combination thereof). The device 805 may include components for bi-directional voice and data communications including components for transmitting and receiving communications, such as a communications manager 820, an input/output (I/O) controller, such as an I/O controller 810, a transceiver 815, one or more antennas 825, at least one memory 830, code 835, and at least one processor 840. These components may be in electronic communication or otherwise coupled (e.g., operatively, communicatively, functionally, electronically, electrically) via one or more buses (e.g., a bus 845).

The I/O controller 810 may manage input and output signals for the device 805. The I/O controller 810 may also manage peripherals not integrated into the device 805. In some cases, the I/O controller 810 may represent a physical connection or port to an external peripheral. In some cases, the I/O controller 810 may utilize an operating system such as iOS®, ANDROID®, MS-DOS®, MS-WINDOWS®, OS/2®, UNIX®, LINUX®, or another known operating system. Additionally, or alternatively, the I/O controller 810 may represent or interact with a modem, a keyboard, a mouse, a touchscreen, or a similar device. In some cases, the I/O controller 810 may be implemented as part of one or more processors, such as the at least one processor 840. In some cases, a user may interact with the device 805 via the I/O controller 810 or via hardware components controlled by the I/O controller 810.

In some cases, the device 805 may include a single antenna. However, in some other cases, the device 805 may have more than one antenna, which may be capable of concurrently transmitting or receiving multiple wireless transmissions. The transceiver 815 may communicate bi-directionally via the one or more antennas 825 using wired or wireless links as described herein. For example, the transceiver 815 may represent a wireless transceiver and may communicate bi-directionally with another wireless transceiver. The transceiver 815 may also include a modem to modulate the packets, to provide the modulated packets to one or more antennas 825 for transmission, and to demodulate packets received from the one or more antennas 825. The transceiver 815, or the transceiver 815 and one or more antennas 825, may be an example of a transmitter 515, a transmitter 615, a receiver 510, a receiver 610, or any combination thereof or component thereof, as described herein.

The at least one memory 830 may include random access memory (RAM) and read-only memory (ROM). The at least one memory 830 may store computer-readable, computer-executable, or processor-executable code, such as the code 835. The code 835 may include instructions that, when executed by the at least one processor 840, cause the device 805 to perform various functions described herein. The code 835 may be stored in a non-transitory computer-readable medium such as system memory or another type of memory. In some cases, the code 835 may not be directly executable by the at least one processor 840 but may cause a computer (e.g., when compiled and executed) to perform functions described herein. In some cases, the at least one memory 830 may include, among other things, a basic I/O system (BIOS) which may control basic hardware or software operation such as the interaction with peripheral components or devices.

The at least one processor 840 may include one or more intelligent hardware devices (e.g., one or more general-purpose processors, one or more DSPs, one or more CPUs, one or more graphics processing units (GPUs), one or more neural processing units (NPUs) (also referred to as neural network processors or deep learning processors (DLPs)), one or more microcontrollers, one or more ASICs, one or more FPGAs, one or more programmable logic devices, discrete gate or transistor logic, one or more discrete hardware components, or any combination thereof). In some cases, the at least one processor 840 may be configured to operate a memory array using a memory controller. In some other cases, a memory controller may be integrated into the at least one processor 840. The at least one processor 840 may be configured to execute computer-readable instructions stored in a memory (e.g., the at least one memory 830) to cause the device 805 to perform various functions (e.g., functions or tasks supporting machine learning based adaptive quantization for LDPC). For example, the device 805 or a component of the device 805 may include at least one processor 840 and at least one memory 830 coupled with or to the at least one processor 840, the at least one processor 840 and the at least one memory 830 configured to perform various functions described herein.

In some examples, the at least one processor 840 may include multiple processors and the at least one memory 830 may include multiple memories. One or more of the multiple processors may be coupled with one or more of the multiple memories, which may, individually or collectively, be configured to perform various functions described herein. In some examples, the at least one processor 840 may be a component of a processing system, which may refer to a system (such as a series) of machines, circuitry (including, for example, one or both of processor circuitry (which may include the at least one processor 840) and memory circuitry (which may include the at least one memory 830)), or components, that receives or obtains inputs and processes the inputs to produce, generate, or obtain a set of outputs. The processing system may be configured to perform one or more of the functions described herein. For example, the at least one processor 840 or a processing system including the at least one processor 840 may be configured to, configurable to, or operable to cause the device 805 to perform one or more of the functions described herein. Further, as described herein, being “configured to,” being “configurable to,” and being “operable to” may be used interchangeably and may be associated with a capability, when executing code 835 (e.g., processor-executable code) stored in the at least one memory 830 or otherwise, to perform one or more of the functions described herein.

The communications manager 820 may support wireless communications in accordance with examples as disclosed herein. For example, the communications manager 820 is capable of, configured to, or operable to support a means for receiving a first code block of one or more code blocks associated with a transport block for the wireless device. The communications manager 820 is capable of, configured to, or operable to support a means for outputting, using a neural network model associated with the wireless device, a set of multiple LDPC quantization values for a set of multiple iterations of an LDPC decoding procedure for the first code block, where the set of multiple LDPC quantization values include respective LDPC quantization values for respective iterations of the set of multiple iterations. The communications manager 820 is capable of, configured to, or operable to support a means for performing one or more iterations of the LDPC decoding procedure for the first code block in accordance with one or more LDPC quantization values of the set of multiple LDPC quantization values output using the neural network model.

By including or configuring the communications manager 820 in accordance with examples as described herein, the device 805 may support techniques for improved communication reliability, reduced latency, improved user experience related to reduced processing, reduced power consumption, more efficient utilization of communication resources, improved coordination between devices, longer battery life, and improved utilization of processing capability.

In some examples, the communications manager 820 may be configured to perform various operations (e.g., receiving, monitoring, transmitting) using or otherwise in cooperation with the transceiver 815, the one or more antennas 825, or any combination thereof. Although the communications manager 820 is illustrated as a separate component, in some examples, one or more functions described with reference to the communications manager 820 may be supported by or performed by the at least one processor 840, the at least one memory 830, the code 835, or any combination thereof. For example, the code 835 may include instructions executable by the at least one processor 840 to cause the device 805 to perform various aspects of machine learning based adaptive quantization for LDPC as described herein, or the at least one processor 840 and the at least one memory 830 may be otherwise configured to, individually or collectively, perform or support such operations.

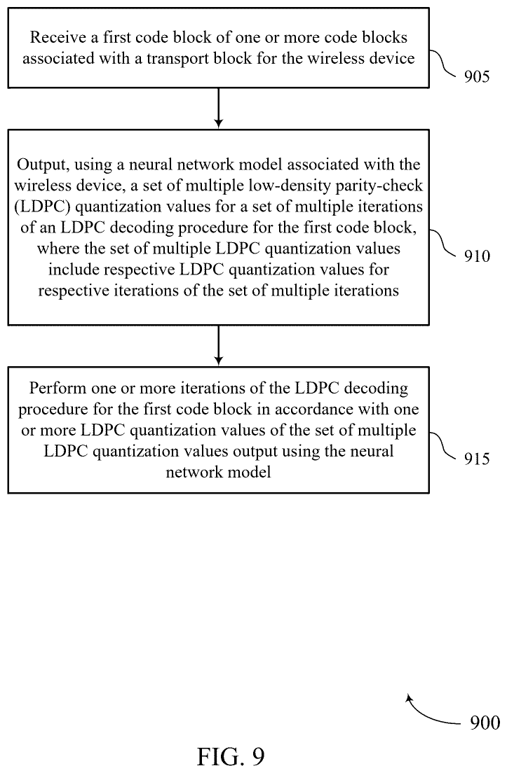

FIG. 9 shows a flowchart illustrating a method 900 that supports machine learning based adaptive quantization for LDPC in accordance with one or more aspects of the present disclosure. The operations of the method 900 may be implemented by a UE or its components as described herein. For example, the operations of the method 900 may be performed by a UE 115 as described with reference to FIGS. 1 through 8. In some examples, a UE may execute a set of instructions to control the functional elements of the UE to perform the described functions. Additionally, or alternatively, the UE may perform aspects of the described functions using special-purpose hardware.

At 905, the method may include receiving a first code block of one or more code blocks associated with a transport block for the wireless device. The operations of 905 may be performed in accordance with examples as disclosed herein. In some examples, aspects of the operations of 905 may be performed by a message monitoring component 725 as described with reference to FIG. 7.

At 910, the method may include outputting, using a neural network model associated with the wireless device, a set of multiple LDPC quantization values for a set of multiple iterations of an LDPC decoding procedure for the first code block, where the set of multiple LDPC quantization values include respective LDPC quantization values for respective iterations of the set of multiple iterations. The operations of 910 may be performed in accordance with examples as disclosed herein. In some examples, aspects of the operations of 910 may be performed by a neural network model component 730 as described with reference to FIG. 7.

At 915, the method may include performing one or more iterations of the LDPC decoding procedure for the first code block in accordance with one or more LDPC quantization values of the set of multiple LDPC quantization values output using the neural network model. The operations of 915 may be performed in accordance with examples as disclosed herein. In some examples, aspects of the operations of 915 may be performed by an LDPC decoder 735 as described with reference to FIG. 7.

The following provides an overview of aspects of the present disclosure:
Aspect 1: A method for wireless communications, at a wireless device, comprising: receiving a first code block of one or more code blocks associated with a transport block for the wireless device; outputting, using a neural network model associated with the wireless device, a plurality of low-density parity-check (LDPC) quantization values for a plurality of iterations of an LDPC decoding procedure for the first code block, wherein the plurality of LDPC quantization values comprise respective LDPC quantization values for respective iterations of the plurality of iterations; and performing one or more iterations of the LDPC decoding procedure for the first code block in accordance with one or more LDPC quantization values of the plurality of LDPC quantization values output using the neural network model.
Aspect 2: The method of aspect 1, further comprising: inputting, into the neural network model, a set of input parameters, wherein the set of input parameters comprises at least mutual information of a plurality of log-likelihood ratios (LLRs) associated with demodulating the first code block and a histogram associated with the plurality of LLRs associated with demodulating the first code block, and wherein the plurality of LDPC quantization values output from the neural network model is based at least in part on the set of input parameters.
Aspect 3: The method of any of aspects 1 through 2, wherein each respective LDPC quantization value of the plurality of LDPC quantization values is associated with a respective set of input parameters, and a given LDPC quantization value is based at least in part on a previous iteration of LLRs output from an LDPC decoder that performs the LDPC decoding procedure.
Aspect 4: The method of any of aspects 1 through 3, wherein performing the one or more iterations of the LDPC decoding procedure for the first code block comprises: performing a first iteration of the one or more iterations in accordance with a first LDPC quantization value of the one or more LDPC quantization values.
Aspect 5: The method of aspect 4, wherein the first iteration of the LDPC decoding procedure results in CRC failure for the first code block, the method further comprising: performing a second iteration of the one or more iterations in accordance with a second LDPC quantization value of the one or more LDPC quantization values; and refraining from performing additional iterations of the plurality of iterations of the LDPC decoding procedure for the first code block based at least in part on the second iteration resulting in CRC pass for the first code block.
Aspect 6: The method of aspect 5, further comprising: performing a second LDPC decoding procedure for a second code block of the one or more code blocks based at least in part on CRC pass for the first code block.
Aspect 7: The method of any of aspects 1 through 6, wherein each of the plurality of iterations of the LDPC decoding procedure results in CRC failure for the first code block, the method further comprising: performing one or more additional iterations of the LDPC decoding procedure for the first code block in accordance with one or more fixed LDPC quantization values, wherein the one or more fixed LDPC quantization values comprise respective fixed LDPC quantization values for respective additional iterations of the one or more additional iterations.
Aspect 8: The method of any of aspects 1 through 7, wherein each of the plurality of iterations of the LDPC decoding procedure results in CRC failure for the first code block, the method further comprising: refraining from decoding additional code blocks of the one or more code blocks based at least in part on each of the plurality of iterations of the LDPC decoding procedure resulting in CRC failure for the first code block.
Aspect 9: The method of any of aspects 1 through 8, wherein the neural network model outputs the plurality of LDPC quantization values for the plurality of iterations of the LDPC decoding procedure for the first code block to an LDPC decoder associated with the wireless device.
Aspect 10: The method of any of aspects 1 through 9, further comprising: training, prior to outputting the plurality of LDPC quantization values, the neural network model in accordance with a multi-class classification, wherein each class of a set of classes associated with the multi-class classification indicates one or more allowed LDPC quantizations values for each respective iteration of the plurality of iterations.
Aspect 11: The method of any of aspects 1 through 10, further comprising: performing, prior to the LDPC decoding procedure of the first code block, a second decoding procedure for the first code block that results in an CRC failure for the first code block, wherein performing the one or more iterations of the LDPC decoding procedure for the first code block is based at least in part on the second decoding procedure resulting in CRC failure for the first code block.
Aspect 12: The method of any of aspects 1 through 11, further comprising: performing, at the neural network model, a first iteration of a prediction procedure that outputs a first LDPC success prediction value associated with decoding the first code block, wherein performing the one or more iterations of the LDPC decoding procedure for the first code block is based at least in part on the first LDPC success prediction value satisfying a prediction value threshold.
Aspect 13: The method of aspect 12, further comprising: performing, at the neural network model, a second iteration of the prediction procedure that outputs a second LDPC success prediction value associated with decoding a second code block of the one or more code blocks; and refraining to perform a second LDPC decoding procedure for the second code block based at least in part on the second LDPC success prediction value not satisfying the prediction value threshold.
Aspect 14: The method of any of aspects 1 through 13, wherein each respective LDPC quantization value indicates a respective quantity of bits for each log-likelihood ratio (LLR) of a set of LLRs for the first code block.
Aspect 15: A wireless device for wireless communications, comprising one or more memories storing processor-executable code, and one or more processors coupled with the one or more memories and individually or collectively operable to execute the code to cause the wireless device to perform a method of any of aspects 1 through 14.
Aspect 16: A wireless device for wireless communications, comprising at least one means for performing a method of any of aspects 1 through 14.
Aspect 17: A non-transitory computer-readable medium storing code for wireless communications, the code comprising instructions executable by one or more processors to perform a method of any of aspects 1 through 14.

It should be noted that the methods described herein describe possible implementations. The operations and the steps may be rearranged, or otherwise modified and other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, a graphics processing unit (GPU), a neural processing unit (NPU), an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration). Any functions or operations described herein as being capable of being performed by a processor may be performed by multiple processors that, individually or collectively, can perform the described functions or operations.

The functions described herein may be implemented using hardware, software executed by a processor, firmware, or any combination thereof. If implemented using software executed by a processor, the functions may be stored as or transmitted using one or more instructions or code of a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk, and Blu-ray disc. Disks may reproduce data magnetically, and discs may reproduce data optically using lasers. Combinations of the above are also included within the scope of computer-readable media. Any functions or operations described herein as being capable of being performed by a memory may be performed by multiple memories that, individually or collectively, can perform the described functions or operations.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” and “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

The term “determine” or “determining” encompasses a variety of actions and, therefore, “determining” can include calculating, computing, processing, deriving, investigating, looking up (such as via looking up in a table, a database, or another data structure), ascertaining, and the like. Also, “determining” can include receiving (e.g., receiving information), accessing (e.g., accessing data stored in memory), and the like. Also, “determining” can include resolving, obtaining, selecting, choosing, establishing, and other such similar actions.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label or other subsequent reference label.

The description set forth herein, in connection with the appended drawings, describes example configurations and does not represent all the examples that may be implemented or that are within the scope of the claims. The term “example” used herein means “serving as an example, instance, or illustration” and not “preferred” or “advantageous over other examples.” The detailed description includes specific details for the purpose of providing an understanding of the described techniques. These techniques, however, may be practiced without these specific details. In some figures, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A wireless device, comprising:
one or more memories storing processor-executable code; and
one or more processors coupled with the one or more memories and individually or collectively operable to execute the code to cause the wireless device to:
receive a first code block of one or more code blocks associated with a transport block for the wireless device;
output, using a neural network model associated with the wireless device, a plurality of low-density parity-check (LDPC) quantization values for a plurality of iterations of an LDPC decoding procedure for the first code block, wherein the plurality of LDPC quantization values comprise respective LDPC quantization values for respective iterations of the plurality of iterations; and
perform one or more iterations of the LDPC decoding procedure for the first code block in accordance with one or more LDPC quantization values of the plurality of LDPC quantization values output using the neural network model.

2. The wireless device of claim 1, wherein the one or more processors are individually or collectively further operable to execute the code to cause the wireless device to:
input, into the neural network model, a set of input parameters, wherein the set of input parameters comprises at least mutual information of a plurality of log-likelihood ratios (LLRs) associated with demodulating the first code block and a histogram associated with the plurality of LLRs associated with demodulating the first code block, and wherein the plurality of LDPC quantization values output from the neural network model is based at least in part on the set of input parameters.

3. The wireless device of claim 1, wherein:
each respective LDPC quantization value of the plurality of LDPC quantization values is associated with a respective set of input parameters, and
a given LDPC quantization value is based at least in part on a previous iteration of LLRs output from an LDPC decoder that performs the LDPC decoding procedure.

4. The wireless device of claim 1, wherein, to perform the one or more iterations of the LDPC decoding procedure for the first code block, the one or more processors are individually or collectively operable to execute the code to cause the wireless device to:
perform a first iteration of the one or more iterations in accordance with a first LDPC quantization value of the one or more LDPC quantization values.

5. The wireless device of claim 4, wherein the first iteration of the LDPC decoding procedure results in cyclic redundancy check (CRC) failure for the first code block, and the one or more processors are individually or collectively further operable to execute the code to cause the wireless device to:
perform a second iteration of the one or more iterations in accordance with a second LDPC quantization value of the one or more LDPC quantization values; and
refrain from performing additional iterations of the plurality of iterations of the LDPC decoding procedure for the first code block based at least in part on the second iteration resulting in CRC pass for the first code block.

6. The wireless device of claim 5, wherein the one or more processors are individually or collectively further operable to execute the code to cause the wireless device to:
perform a second LDPC decoding procedure for a second code block of the one or more code blocks based at least in part on CRC pass for the first code block.

7. The wireless device of claim 1, wherein each of the plurality of iterations of the LDPC decoding procedure results in cyclic redundancy check (CRC) failure for the first code block, and the one or more processors are individually or collectively further operable to execute the code to cause the wireless device to:
perform one or more additional iterations of the LDPC decoding procedure for the first code block in accordance with one or more fixed LDPC quantization values, wherein the one or more fixed LDPC quantization values comprise respective fixed LDPC quantization values for respective additional iterations of the one or more additional iterations.

8. The wireless device of claim 1, wherein each of the plurality of iterations of the LDPC decoding procedure results in cyclic redundancy check (CRC) failure for the first code block, and the one or more processors are individually or collectively further operable to execute the code to cause the wireless device to:
refrain from decoding additional code blocks of the one or more code blocks based at least in part on each of the plurality of iterations of the LDPC decoding procedure resulting in CRC failure for the first code block.

9. The wireless device of claim 1, wherein the neural network model outputs the plurality of LDPC quantization values for the plurality of iterations of the LDPC decoding procedure for the first code block to an LDPC decoder associated with the wireless device.

10. The wireless device of claim 1, wherein the one or more processors are individually or collectively further operable to execute the code to cause the wireless device to:
training, prior to output the plurality of LDPC quantization values, the neural network model in accordance with a multi-class classification, wherein each class of a set of classes associated with the multi-class classification indicates one or more allowed LDPC quantizations values for each respective iteration of the plurality of iterations.

11. The wireless device of claim 1, wherein the one or more processors are individually or collectively further operable to execute the code to cause the wireless device to:
perform, prior to the LDPC decoding procedure of the first code block, a second decoding procedure for the first code block that results in a cyclic redundancy check (CRC) failure for the first code block, wherein performing the one or more iterations of the LDPC decoding procedure for the first code block is based at least in part on the second decoding procedure resulting in CRC failure for the first code block.

12. The wireless device of claim 1, wherein the one or more processors are individually or collectively further operable to execute the code to cause the wireless device to:
perform, at the neural network model, a first iteration of a prediction procedure that outputs a first LDPC success prediction value associated with decoding the first code block, wherein performing the one or more iterations of the LDPC decoding procedure for the first code block is based at least in part on the first LDPC success prediction value satisfying a prediction value threshold.

13. The wireless device of claim 12, wherein the one or more processors are individually or collectively further operable to execute the code to cause the wireless device to:
perform, at the neural network model, a second iteration of the prediction procedure that outputs a second LDPC success prediction value associated with decoding a second code block of the one or more code blocks; and
refrain to perform a second LDPC decoding procedure for the second code block based at least in part on the second LDPC success prediction value not satisfying the prediction value threshold.

14. The wireless device of claim 1, wherein each respective LDPC quantization value indicates a respective quantity of bits for each log-likelihood ratio (LLR) of a set of LLRs for the first code block.

15. A method for wireless communications, at a wireless device, comprising:
receiving a first code block of one or more code blocks associated with a transport block for the wireless device;
outputting, using a neural network model associated with the wireless device, a plurality of low-density parity-check (LDPC) quantization values for a plurality of iterations of an LDPC decoding procedure for the first code block, wherein the plurality of LDPC quantization values comprise respective LDPC quantization values for respective iterations of the plurality of iterations; and
performing one or more iterations of the LDPC decoding procedure for the first code block in accordance with one or more LDPC quantization values of the plurality of LDPC quantization values output using the neural network model.

16. The method of claim 15, further comprising:
inputting, into the neural network model, a set of input parameters, wherein the set of input parameters comprises at least mutual information of a plurality of log-likelihood ratios (LLRs) associated with demodulating the first code block and a histogram associated with the plurality of LLRs associated with demodulating the first code block, and wherein the plurality of LDPC quantization values output from the neural network model is based at least in part on the set of input parameters.

17. The method of claim 16, wherein:
each respective LDPC quantization value of the plurality of LDPC quantization values is associated with a respective set of input parameters; and
a given LDPC quantization value is based at least in part on a previous iteration of LLRs output from an LDPC decoder that performs the LDPC decoding procedure.

18. The method of claim 15, wherein performing the one or more iterations of the LDPC decoding procedure for the first code block comprises:
performing a first iteration of the one or more iterations in accordance with a first LDPC quantization value of the one or more LDPC quantization values.

19. The method of claim 18, wherein the first iteration of the LDPC decoding procedure results in cyclic redundancy check (CRC) failure for the first code block, the method further comprising:
performing a second iteration of the one or more iterations in accordance with a second LDPC quantization value of the one or more LDPC quantization values; and
refraining from performing additional iterations of the plurality of iterations of the LDPC decoding procedure for the first code block based at least in part on the second iteration resulting in CRC pass for the first code block.

20. The method of claim 19, further comprising:
performing a second LDPC decoding procedure for a second code block of the one or more code blocks based at least in part on CRC pass for the first code block.

21. The method of claim 15, wherein each of the plurality of iterations of the LDPC decoding procedure results in cyclic redundancy check (CRC) failure for the first code block, the method further comprising:
performing one or more second iterations of the LDPC decoding procedure for the first code block in accordance with one or more fixed LDPC quantization values, wherein the one or more fixed LDPC quantization values comprise respective fixed LDPC quantization values for respective second iterations of the one or more second iterations.

22. The method of claim 15, wherein each of the plurality of iterations of the LDPC decoding procedure results in cyclic redundancy check (CRC) failure for the first code block, the method further comprising:
refraining from decoding additional code blocks of the one or more code blocks based at least in part on each of the plurality of iterations of the LDPC decoding procedure resulting in CRC failure for the first code block.

23. The method of claim 15, wherein the neural network model outputs the plurality of LDPC quantization values for the plurality of iterations of the LDPC decoding procedure for the first code block to an LDPC decoder associated with the wireless device.

24. The method of claim 15, further comprising:
training, prior to outputting the plurality of LDPC quantization values, the neural network model in accordance with a multi-class classification, wherein each class of a set of classes associated with the multi-class classification indicates one or more allowed LDPC quantizations values for each respective iteration of the plurality of iterations.

25. The method of claim 15, further comprising:
performing, prior to the LDPC decoding procedure of the first code block, a second decoding procedure for the first code block that results in a cyclic redundancy check (CRC) failure for the first code block, wherein performing the one or more iterations of the LDPC decoding procedure for the first code block is based at least in part on the second decoding procedure resulting in CRC failure for the first code block.

26. The method of claim 15, further comprising:
performing, at the neural network model, a first iteration of a prediction procedure that outputs a first LDPC success prediction value associated with decoding the first code block, wherein performing the one or more iterations of the LDPC decoding procedure for the first code block is based at least in part on the first LDPC success prediction value satisfying a prediction value threshold.

27. The method of claim 26, further comprising:
performing, at the neural network model, a second iteration of the prediction procedure that outputs a second LDPC success prediction value associated with decoding a second code block of the one or more code blocks; and
refraining to perform a second LDPC decoding procedure for the second code block based at least in part on the second LDPC success prediction value not satisfying the prediction value threshold.

28. The method of claim 15, wherein each respective LDPC quantization value indicates a respective quantity of bits for each log-likelihood ratio (LLR) of a set of LLRs for the first code block.

29. A wireless device for wireless communications, comprising:
means for receiving a first code block of one or more code blocks associated with a transport block for the wireless device;
means for outputting, using a neural network model associated with the wireless device, a plurality of low-density parity-check (LDPC) quantization values for a plurality of iterations of an LDPC decoding procedure for the first code block, wherein the plurality of LDPC quantization values comprise respective LDPC quantization values for respective iterations of the plurality of iterations; and
means for performing one or more iterations of the LDPC decoding procedure for the first code block in accordance with one or more LDPC quantization values of the plurality of LDPC quantization values output using the neural network model.

30. A non-transitory computer-readable medium storing code for wireless communications at a wireless device, the code comprising instructions executable by one or more processors to:
receive a first code block of one or more code blocks associated with a transport block for the wireless device;
output, using a neural network model associated with the wireless device, a plurality of low-density parity-check (LDPC) quantization values for a plurality of iterations of an LDPC decoding procedure for the first code block, wherein the plurality of LDPC quantization values comprise respective LDPC quantization values for respective iterations of the plurality of iterations; and
perform one or more iterations of the LDPC decoding procedure for the first code block in accordance with one or more LDPC quantization values of the plurality of LDPC quantization values output using the neural network model.
